(19) United States
(12) Patent Application Publication
(10) Pub. No.: US 2015/0155684 A1
(43) Pub. Date: Jun. 4, 2015

(54) METHOD FOR MANUFACTURING SEMICONDUCTOR LASER DEVICE

(71) Applicant: ROHM CO., LTD., Kyoto (JP)

(72) Inventors: Junichi KASHIWAGI, Kyoto (JP); Kuniyoshi OKAMOTO, Kyoto (JP); Taketoshi TANAKA, Kyoto (JP); Masashi KUBOTA, Kyoto (JP)

(21) Appl. No.: 14/618,483

(22) Filed: Feb. 10, 2015

Related U.S. Application Data
(62) Division of application No. 13/312,697, filed on Dec. 6, 2011.

(30) Foreign Application Priority Data
Dec. 7, 2010 (JP) 2010-272761
Dec. 7, 2010 (JP) 2010-272762

(51) Int. Cl. H01S 5/02; H01S 5/343; H01S 5/22

(52) U.S. Cl. CPC H01S 5/0202; H01S 5/22; H01S 5/34333

(57) ABSTRACT

A method for manufacturing a semiconductor laser device includes preparing an original substrate having a plurality of semiconductor laser device regions arrayed in a matrix, and a plurality of ridges formed in stripes so as to pass through each of the plurality of semiconductor laser device regions that are aligned in one direction. A scribing process is applied to the original substrate along cutting lines set along boundaries of the plurality of semiconductor laser device regions from a rear surface at an opposite side of a top surface at which the ridges are formed. A blade is applied to the original substrate along each cutting line from the top surface of the original substrate for dividing the original substrate along the cutting line.

This is a Divisional of U.S. application Ser. No. 13/312,697, filed on Dec. 6, 2011, the subject matter of which is incorporated herein by reference.

### BACKGROUND OF THE INVENTION

1. Field of the Invention

The present invention relates to a semiconductor laser device made of a group III nitride semiconductor.

2. Description of Related Art

A group III nitride semiconductor is a group III-V semiconductor in which nitrogen is used as the group V element. Representative examples include aluminum nitride (AlN), gallium nitride (GaN), and indium nitride (InN). The group III nitride semiconductor can generally be expressed as: Al_{X}In_{Y}Ga_{1-X-Y}N (where 0≦X≦1, 0≦Y≦1, and 0≦X+Y≦1).

Laser light sources of short wavelengths, such as blue and green, are coming to be used in such fields as high-density recording onto optical disks as represented by DVDs, image processing, medical equipment, measuring instruments, etc. Such a short-wavelength laser light source is arranged, for example, from a laser diode that uses a GaN semiconductor.

United States Patent Application Publication No. 2009/0238227 A1 discloses a semiconductor laser device that is improved in emission efficiency by using an m-plane as a crystal growth surface. This semiconductor laser device has a semiconductor laminate structure that includes a light emitting layer that contains In, a p-type guide layer and an n-type guide layer disposed so as to sandwich the light emitting layer, and a p-type clad layer and an n-type clad layer disposed so as to sandwich the above components.

The semiconductor laminate structure has a pair of end surfaces orthogonal to a ridge at both ends of the ridge. The pair of end surfaces are mirror surfaces formed by cleavage and form laser resonance surfaces that reflect light propagating through a waveguide.

The semiconductor laser device is prepared by being cut out from an original substrate in which a plurality of individual device regions are arrayed in a matrix. A plurality of ridges are formed in stripes in the original substrate. In cutting the original substrate, first, division guide grooves are formed by laser processing on a surface corresponding to a top surface (surface at the ridge side) of the semiconductor laser device as described in United States Patent Application Publication No. 2009/0101927 A1. Thereafter, a blade is applied from a rear surface side of the original substrate and an external force is applied to divide the original substrate. The laser resonance surfaces are formed by dividing (cleaving) the original substrate along a direction intersecting the plurality of ridges formed in stripes. To avoid damaging a laser resonance surface in a vicinity of a ridge (waveguide), the division guide grooves are formed in a perforated, discontinuous pattern that is discontinuous at a portion near the ridge.

### SUMMARY OF THE INVENTION

An emission wavelength can be elongated by increasing an In composition of the light emitting layer. However, if the light emitting layer is grown using a group III nitride semiconductor having the m-plane as the major growth surface, the In composition of the light emitting layer cannot be made very high. According to a most recent research by the present inventors, an upper limit emission wavelength of a laser diode prepared from a group III nitride semiconductor having the m-plane as the major growth surface is approximately 500 nm. It is thus difficult to realize a semiconductor laser device of a green wavelength range (510 nm to 540 nm).

Thus, a first object of the present invention is to provide a semiconductor laser device with which wavelength elongation is realized using a semiconductor laminate structure made of a group III nitride semiconductor.

Also, although division guide grooves of a discontinuous pattern are effective for division along a crystal plane of good cleavability, a satisfactory cleavage plane is not necessarily obtained when substrate division is performed along a crystal plane that is not necessarily adequate in cleavability. A degree of freedom of selection of laser resonance surfaces is thus limited if application of the prior art of United States Patent Application Publication No. 2009/0101927 A1 is premised. Thus, even if a crystal growth surface and a ridge direction of a semiconductor are to be selected in accordance with required specifications, a semiconductor laser device with the required specifications is difficult to realize because the laser resonance surfaces cannot be formed at satisfactory cleavage planes.

Thus, a second object of the present invention is to provide a semiconductor laser device and a method for manufacturing thereof with which a degree of freedom of selection of laser resonance surfaces can be increased to enable a degree of freedom of design to be increased and a contribution to be made to improvement in characteristics.

The above and yet other objects, features, and effects of the present invention will be made clearer by the following description of the preferred embodiments with reference to the attached drawings.

### BRIEF DESCRIPTION OF THE DRAWINGS

FIG. 1 is a perspective view for describing an arrangement of a semiconductor laser device according to a preferred embodiment of the present invention.

FIG. 2 is a longitudinal sectional view taken along the line II-II of FIG. 1.

FIG. 3 is a transverse sectional view taken along the line III-III of FIG. 1.

FIG. 4 is a diagrammatic view of a unit cell of a crystal structure of a group III nitride semiconductor.

FIG. 5 shows a strain amount (%) of an AlₓGa₁₋ₓN layer (where 0≦x≦1) grown coherently on a GaN monocrystal substrate having a {20-21} plane as a major surface.

FIG. 6 shows results of measuring PL (photoluminescence) polarization characteristics of a group III nitride semiconductor (sample) grown with the {20-21} plane as a crystal growth surface.

FIG. 7 is a diagrammatic perspective view of a wafer that is an original substrate for manufacturing a semiconductor laser diode.

FIGS. 8A-8C are diagrammatic perspective views for describing, in outline, a procedure for dividing the wafer into individual devices (semiconductor laser devices).

FIG. 9 is a partially enlarged plan view for describing positioning of p-side electrodes and receiving portions on a top surface of the wafer.

FIG. 10A is a bottom view of a first formation pattern example of n-side electrodes.

FIG. 10B is a bottom view of a second formation pattern example of n-side electrodes.

FIG. 10C is a bottom view of a third formation pattern example of n-side electrodes.

FIG. 11A and FIG. 11B are explanatory diagrams for describing a specific example of primary cleavage.

FIG. 12A and FIG. 12B are explanatory diagrams for describing a specific example of secondary cleavage.

FIG. 13A and FIG. 13B are explanatory diagrams for describing another specific example of secondary cleavage.

FIG. 14 is a perspective view for describing an arrangement of a semiconductor laser device according to another preferred embodiment of the present invention.

FIG. 15 is a longitudinal sectional view taken along the line XV-XV of FIG. 14.

FIG. 16 is a transverse sectional view taken along the line XVI-XVI of FIG. 14.

FIG. 17A is a histogram of results of measuring threshold currents of a plurality of samples (semiconductor laser devices) according to a comparative example in which primary cleavage was performed by performing a scribing step from a top surface side of a wafer and performing a breaking step from a rear surface side. FIG. 17B is a histogram of results of measuring the threshold currents of a plurality of samples (semiconductor laser devices) according to an inventive example in which primary cleavage was performed by performing a scribing step from a rear surface side of a wafer and performing a breaking step from a top surface side.

FIG. 18A is a histogram of results of measuring slope efficiencies of the plurality of samples according to the comparative example, and FIG. 18B is a histogram of results of measuring the slope efficiencies of the plurality of samples according to the inventive example.

FIG. 19A is a histogram of results of measuring operating currents of the plurality of samples according to the comparative example, and FIG. 19B is a histogram of results of measuring the operating currents of the plurality of samples according to the inventive example.

### DETAILED DESCRIPTION OF THE PREFERRED EMBODIMENTS

A preferred embodiment according to a first aspect of the present invention provides a semiconductor laser device including a semiconductor laminate structure made of a group III nitride semiconductor having a semipolar plane as a crystal growth surface. The semiconductor laminate structure includes a light emitting layer that contains In, a p-type guide layer disposed at one side of the light emitting layer, an n-type guide layer disposed at another side of the light emitting layer, a p-type clad layer disposed at an opposite side of the p-type guide layer to the light emitting layer, and an n-type clad layer disposed at an opposite side of the n-type guide layer to the light emitting layer. The semiconductor laminate structure includes a rectilinear waveguide formed parallel to a projection vector of a c-axis onto the crystal growth surface, and a pair of laser resonance surfaces formed of cleavage planes perpendicular to the projection vector.

According to a most recent research by the present inventors, it was found that by using a group III nitride semiconductor grown with a semipolar surface being as a major growth surface, alight emitting layer with a high In composition can be formed and a semiconductor laser device of a green wavelength range can be realized. Thus, in the present invention, the semiconductor laminate structure that makes up a laser diode structure is formed of a group III nitride semiconductor having a semipolar plane as the crystal growth surface. With the group III nitride semiconductor having the semipolar plane as the crystal growth surface, influence of an internal electric field is small and thus a semiconductor laser device of high emission efficiency can be realized in the same manner as in a case of a group III nitride semiconductor having an m-plane or other nonpolar plane as the crystal growth surface.

By the most recent research by the present inventor, on the other hand, it became clear that with a group III nitride semiconductor crystal having a semipolar plane as a major surface, unless cleavage planes (laser resonance surfaces) are selected appropriately, cleavage planes that are adequately smooth as laser resonance surfaces cannot be obtained. Thus, in the present invention, the rectilinear waveguide is arranged parallel to the projection vector of the c-axis onto the crystal growth surface (semipolar plane) of the semiconductor laminate structure. The laser resonance surfaces are formed of the cleavage planes perpendicular to the waveguide. When the laser resonance surfaces are selected in this manner, the laser resonance surfaces are formed of cleavage planes of good flatness. Consequently, a semiconductor laser device with excellent characteristics can be realized.

To describe more specifically, c-axis direction and a-axis direction lattice constants of GaN, which is a typical base substrate material, are 5.185 Å and 3.189 Å, respectively. The c-axis direction and a-axis direction lattice constants of AlN are 4.982 Å and 3.112 Å, respectively. The difference of the c-axis direction lattice constants is thus greater than the difference of the a-axis direction lattice constants. Thus, when Al_{X}Ga_{1-X}N (where 0<X≦1) is grown on a GaN substrate, a strain amount in the a-axis direction is greater than a strain amount in the c-axis direction.

Thus, in the present invention, the rectilinear waveguide is arranged in the direction parallel to the projection vector of the c-axis and the laser resonance surfaces are formed of the cleavage planes perpendicular to the waveguide. Thus, in forming the laser resonance surfaces by cleavage of the crystal, use can be made of a large internal stress (strain) accumulated in the c-axis direction and cleavage planes of good flatness can be obtained. A semiconductor laser device of excellent emission efficiency can thereby be realized.

Further, the present inventors measured PL (photoluminescence) polarization characteristics of the group III nitride semiconductor grown with the semipolar plane as the major growth surface. The measurement results indicated that an a-axis projection direction polarization (polarization component in which a field component lies along the a-axis projection direction) is highest in intensity. Thus, by setting a resonator length direction (longitudinal direction of the waveguide) along a c-axis projection direction, effective use can be made of TE mode light and the emission efficiency can be improved further.

Thus, by the present invention, a semiconductor laser device, with which wavelength elongation can be realized using a group III nitride semiconductor and yet which is excellent in emission efficiency, can be provided.

A specific example of the semipolar plane is a {20-21} plane, and in this case, the laser resonance surfaces are preferably set at {−1014} planes. Crystal planes orthogonal to the {20-21} plane are the {−1014} planes and {11-20} planes. The {−1014} planes are crystal planes perpendicular to the projection vector of the c-axis onto the {20-21} plane and the {11-20} planes are crystal planes perpendicular to the projection vector of the a-axis onto the {20-21} plane. Of these, by making the {−1014} planes to be the laser resonance surfaces, the laser resonance surfaces can be formed of cleavage planes of good flatness.

A {11-22} plane and a {01-12} plane can be cited as other examples of semipolar planes.

In a preferred embodiment of the present invention, the semiconductor laminate structure includes a ridge extending along the waveguide and between the pair of laser resonance surfaces, and the semiconductor laser device further includes a top surface electrode formed at a top surface of the semiconductor laminate structure at the side at which the ridge is disposed, and a receiving portion disposed at a position of the top surface of the semiconductor laminate structure that is separated from the ridge in a width direction orthogonal to a longitudinal direction of the ridge, has a height equal to or greater than the ridge, has a length in the width direction that is greater than a width of the ridge, and is spaced apart by an interval from the top surface electrode.

With this arrangement, the laser resonance surfaces can be formed by forming division guide grooves by performing processing from a rear surface (surface at the opposite side of the ridge) of the semiconductor laminate structure and dividing (cleaving) the original substrate by applying a blade from the top surface side of the semiconductor laminate structure and applying an external force. The processing from the rear surface of the semiconductor laminate structure can be performed without flawing the ridge (waveguide) and can thus be performed in a continuous linear pattern extending in a direction perpendicular to the waveguide. Stable division (cleavage) can thus be performed when the external force is applied. Moreover, the external force from the blade can be made to act on the receiving portion. The original substrate can thereby be divided (cleaved) to form laser resonance surfaces formed of satisfactory cleavage planes while protecting the ridge. Moreover, the length of the receiving portion in the width direction of the semiconductor laminate structure (direction parallel to the cleavage planes and the crystal growth surface; resonator width direction) is greater than the width of the ridge and thus the external force can be received reliably. Also, the receiving portion is spaced apart by the interval from the top surface electrode and thus the top surface electrode is not flawed when the external force is received. Current leak and other problems can thus be avoided.

A preferred embodiment of the present invention further includes a rear surface electrode formed at the rear surface at the opposite side to the top surface of the semiconductor laminate structure and having, at peripheral edges, end surface recessed portions that are recessed inward from the pair of laser resonance surfaces. With this arrangement, the peripheral edges of the rear surface electrode have the end surface recessed portions that are recessed inward from the laser resonance surfaces and thus processing from the rear surface side of the semiconductor laminate structure can be performed using the end surface recessed portions as guide marks.

A preferred embodiment according to a second aspect of the present invention provides a semiconductor laser device including a semiconductor laminate structure having a light emitting layer, a p-type guide layer disposed at one side of the light emitting layer, an n-type guide layer disposed at another side of the light emitting layer, a p-type clad layer disposed at an opposite side of the p-type guide layer to the light emitting layer, and an n-type clad layer disposed at an opposite side of the n-type guide layer to the light emitting layer. The semiconductor laminate structure includes a rectilinear ridge formed at a top surface side, a pair of laser resonance surfaces formed at both ends in a longitudinal direction of the ridge so as to be orthogonal to the ridge, and end surface processing marks formed at the pair of laser resonance surfaces in lower edge regions continuous to a rear surface of the semiconductor laminate structure.

With this arrangement, each laser resonance surface has the end surface processing mark in the lower edge region continuous to the rear surface (surface opposite to the ridge) of the semiconductor laminate structure. That is, with this semiconductor laser device, the end surface processing marks are formed by applying processing from the rear surface side of the semiconductor laminate structure, the original substrate is cleaved by applying a blade from the top surface side (side on which the ridge is formed) of the semiconductor laminate structure and applying an external force, and the laser resonance surfaces can be formed by the cleavage planes. Each end surface processing mark is formed at the rear surface side at which the ridge is not formed and can be formed as a continuous pattern because there is no need to form the mark as a discontinuous pattern having a discontinuous portion near the ridge. Cleavage by application of the external force from the top surface side can thus be performed with stability and satisfactory cleavage planes can thus be obtained. More specifically, even if a crystal plane perpendicular to the ridge is a crystal plane that is not adequate in cleavability, the semiconductor laminate structure can be cleaved satisfactorily along such a crystal plane. Degrees of freedom of selection of the crystal growth surface for forming the semiconductor laminate structure and the ridge direction are thus increased and a degree of freedom of design of the semiconductor laser device is thus increased. A semiconductor laser device with the required specifications can thus be realized more readily. Also, characteristics of the semiconductor laser device can be improved because the laser resonance surfaces can be formed with the satisfactory cleavage planes. More specifically, decrease in threshold current, increase in slope efficiency, reduction in operating current, etc., can be achieved.

In a preferred embodiment of the present invention, the end surface processing marks are continuous across an entire width direction of the semiconductor laminate structure. “Width direction” refers to a direction (resonator width direction) that is orthogonal to the longitudinal direction of the ridge (resonator length direction) and is parallel to the crystal growth surface of the semiconductor laminate structure. With this arrangement, the original substrate can be divided (cleaved) by performing processing across the entire width direction of the semiconductor laminate structure from the rear surface side and thereafter applying a blade from the top surface side of the semiconductor laminate structure and applying an external force. Laser resonance surfaces formed from satisfactory cleavage planes can thereby be provided even if the crystal planes perpendicular to the ridge are crystal planes of poor cleavability.

In a preferred embodiment of the present invention, a thickness of each end surface processing mark is no less than 10% of a thickness of the semiconductor laminate structure. With this arrangement, the laser resonance surfaces can be formed from even more satisfactory cleavage planes because the end surface processing marks have adequate thickness. The semiconductor laser device can thereby be improved in characteristics. The “thickness of each end surface processing mark” is a length along a lamination direction (direction perpendicular to the crystal growth surface) of the semiconductor laminate structure.

In a preferred embodiment of the present invention, the semiconductor laminate structure is made of a group III nitride semiconductor having an m-plane as the crystal growth surface and the laser resonance surfaces are c-planes. With this arrangement, the semiconductor laminate structure is made of the group III nitride semiconductor having the m-plane as the crystal growth surface. In this case, by taking a c-axis direction to be the longitudinal direction of the ridge (direction of the waveguide; resonator length direction), TE mode laser emission can be made to occur with high efficiency. The laser resonance surfaces are the c-planes because the c-axis direction is taken to be the longitudinal direction of the ridge. By forming end surface processing marks of a continuous pattern from the rear surface side of the semiconductor laminate structure, cleavage of the group III nitride semiconductor structure (semiconductor laminate structure) along the c-plane can be performed with stability. Laser resonance surfaces formed of satisfactory cleavage planes can thus be provided.

The group III nitride semiconductor is a group III-V semiconductor in which nitrogen is used as the group V element. Representative examples include aluminum nitride (AlN), gallium nitride (GaN), and indium nitride (InN). The group III nitride semiconductor can generally be expressed as: Al_{X}In_{Y}Ga_{1-X-Y}N (where 0≦X≦1, 0≦Y≦1, and 0≦X+Y≦1).

In a preferred embodiment of the present invention, the semiconductor laminate structure is made of a group III nitride semiconductor having a semipolar plane as the crystal growth surface and the ridge is formed parallel to a projection vector of the c-axis onto the crystal growth surface and the laser resonance surfaces are formed of cleavage planes perpendicular to the projection vector.

A specific example of the semipolar plane is a {20-21} plane, and in this case, the laser resonance surfaces are preferably set at {−1014} planes. Crystal planes orthogonal to the {20-21} plane are the {−1014} planes and {11-20} planes. The {−1014} planes are crystal planes perpendicular to the projection vector of the c-axis onto the {20-21} plane and the {11-20} planes are crystal planes perpendicular to the projection vector of the a-axis onto the {20-21} plane. Of these, by making the {−1014} planes to be the laser resonance surfaces, the laser resonance surfaces can be formed of cleavage planes of good flatness.

A {11-22} plane and a {01-12} plane can be cited as other examples of semipolar planes.

A semiconductor laser device according to a preferred embodiment of the present invention includes a top surface electrode formed at a top surface of the semiconductor laminate structure and a receiving portion disposed at a position of the top surface of the semiconductor laminate structure that is separated from the ridge in a width direction orthogonal to the longitudinal direction of the ridge, has a height equal to or greater than the ridge, has a length in the width direction that is greater than a width of the ridge, and is spaced apart by an interval from the top surface electrode.

With this arrangement, by applying a blade from the top surface side of the semiconductor laminate structure and applying an external force, the external force can be made to act on the receiving portion. The original substrate can thereby be divided (cleaved) to form laser resonance surfaces formed of satisfactory cleavage planes while protecting the ridge. Moreover, the length of the receiving portion in the width direction of the semiconductor laminate structure (direction parallel to the cleavage planes and the crystal growth surface; resonator width direction) is greater than the width of the ridge and thus the external force can be received reliably. Also, the receiving portion is spaced apart by the interval from the top surface electrode and thus the top surface electrode is not flawed when the external force is received. Current leak and other problems can thus be avoided.

The semiconductor laser device according to the preferred embodiment of the present invention further includes a rear surface electrode formed at the rear surface of the semiconductor laminate structure and having, at peripheral edges, end surface recessed portions that are recessed inward from the pair of laser resonance surfaces. With this arrangement, the peripheral edges of the rear surface electrode have the end surface recessed portions that are recessed inward from the laser resonance surfaces and thus processing from the rear surface side of the semiconductor laminate structure can be performed using the end surface recessed portions as guide marks.

In a preferred embodiment of the present invention, the semiconductor laminate structure has a pair of side surfaces parallel to the longitudinal direction of the ridge and side surface processing marks formed at the pair of side surfaces in lower edge regions continuous to the rear surface of the semiconductor laminate structure. With this arrangement, division related to the side surfaces parallel to the ridge can be performed by performing processing of the original substrate from the rear surface side of the semiconductor laminate structure and thereafter applying a blade from the top surface side of the semiconductor laminate structure and applying an external force to the original substrate. The processing from the rear surface side can be applied as a continuous pattern and deep processing can be applied as necessary because there is no danger of flawing the waveguide. Division of the original substrate along the side surfaces of the semiconductor laminate structure can thereby be performed with stability.

In a preferred embodiment of the present invention, a rear surface electrode formed at the rear surface of the semiconductor laminate structure has, at peripheral edges, side surface recessed portions that are recessed inward from the pair of side surfaces. With this arrangement, the rear surface electrode has the side surface recessed portions that are recessed inward from the side surfaces and thus processing from the rear surface side of the semiconductor laminate structure can be performed using the side surface recessed portions as guide marks.

In a preferred embodiment of the present invention, the semiconductor laminate structure has a pair of side surfaces parallel to the longitudinal direction of the ridge and side surface processing marks formed at the pair of side surfaces in upper edge regions continuous to the top surface of the semiconductor laminate structure. With this arrangement, division related to the side surfaces parallel to the ridge can be performed by performing processing of the original substrate from the top surface side of the semiconductor laminate structure and thereafter applying a blade to the original substrate from the rear surface side of the semiconductor laminate structure and applying an external force. In regard to the side surface, processing of a continuous pattern can be applied from the top surface side as well because there is no need to avoid the ridge and also, deep processing can be applied as necessary because there is no danger of flawing the waveguide. Division of the original substrate along the side surfaces of the semiconductor laminate structure can thereby be performed with stability.

In a preferred embodiment of the present invention, the side surface processing marks are continuous across the entire length direction of the semiconductor laminate structure. With this arrangement, the original substrate can be divided along a direction parallel to the ridge upon applying processing across the entire length direction (direction parallel to the longitudinal direction of the ridge) of the semiconductor laminate structure. Division related to the side surfaces of the semiconductor laminate structure can thereby be performed with greater stability.

In a preferred embodiment of the present invention, a thickness of each side surface processing mark is no less than 80% of the thickness of the semiconductor laminate structure. With this arrangement, the original substrate can be divided reliably along the side surface processing marks because the side surface processing marks are adequately thick in thickness. Division related to the side surfaces of the semiconductor laminate structure can thereby be performed with greater stability. The “thickness of each side surface processing mark” is the length along a direction perpendicular to the crystal growth surface of the semiconductor laminate structure.

The present invention further provides a method for manufacturing semiconductor laser device that includes a step of preparing an original substrate having a plurality of semiconductor laser device regions arrayed in a matrix and having a plurality of ridges formed in stripes so as to pass through each of the plurality of semiconductor laser device regions that are aligned in one direction, a scribing step of applying a scribing process to the original substrate along cutting lines set along boundaries of the plurality of semiconductor laser device regions from a rear surface at an opposite side of a top surface at which the ridges are formed, and a dividing step of applying a blade to the original substrate along each cutting line from the top surface of the original substrate and dividing the original substrate along the cutting line.

With the present method, the scribing process is performed from the rear surface of the original substrate and thereafter, the original substrate is divided (cleaved) by applying the blade from the top surface side of the original substrate and applying an external force in a direction (more specifically, a perpendicular direction) that intersects the top surface of the original substrate. By performing such a scribing process and dividing (cleaving) along the cutting lines orthogonal to the ridges, the laser resonance surfaces formed of the cleavage planes perpendicular to the ridges can be obtained. The scribing process is performed from the rear surface side at which the ridges are not formed and thus a scribing process of a continuous pattern can be performed without the need to form a discontinuous pattern having discontinuous portions near the ridges. Cleaving that is performed with the blade being applied from the top surface side can thus be performed with stability, and satisfactory cleavage planes can thus be obtained. More specifically, even if a crystal plane perpendicular to the ridges is a crystal plane that is not adequate in cleavability, the original substrate can be cleaved satisfactorily along such a crystal plane. Degrees of freedom of selection of the crystal growth surface for forming the semiconductor laminate structure that makes up the semiconductor laser diode structure and the ridge direction are thus increased and a degree of freedom of design of the semiconductor laser device is thus increased. A semiconductor laser device with the required specifications can thus be realized more readily. Also, a contribution can be made to the improvement in characteristics of the semiconductor laser device because the laser resonance surfaces formed of the satisfactory cleavage planes can be provided.

In a preferred embodiment of the present invention, the scribing step includes a step of applying the scribing process to the original substrate in a continuous manner along the cutting lines. With this method, the scribing process of a continuous pattern is performed, and thus stable division (cleaving) of the original substrate is possible and accordingly, laser resonance surfaces formed of satisfactory cleavage planes can be formed.

In a preferred embodiment of the present invention, the cutting lines include end surface cutting lines set along a direction orthogonal to the ridges, and by performing the dividing step along the end surface cutting lines, the laser resonance surfaces formed of cleavage planes orthogonal to the ridges are formed.

With this method, division of the original substrate in relation to the end surface cutting lines orthogonal to the ridges is performed by the scribing process being performed from the rear surface side and the external force being applied from the top surface side. Laser resonance surfaces formed of stable cleavage planes can thereby be formed. A depth of the scribing process performed along the end surface cutting lines is preferably no less than 10% of a thickness of the original substrate.

In a preferred embodiment of the present invention, the cutting lines include side surface cutting lines set along a longitudinal direction of the ridges and side surfaces parallel to the ridges are formed by performing the dividing step along the side surface cutting lines.

With this method, division of the original substrate in relation to the side surface cutting lines parallel to the ridges is performed by the scribing process being performed from the rear surface side and the external force being applied from the top surface side. Division of the original substrate in relation to the side surfaces of the semiconductor laser device can thereby be performed with stability. To perform the division with further stability, a depth of the scribing process performed in relation to the side surface cutting lines is preferably no less than 80% of the thickness of the original substrate.

In a preferred embodiment of the present invention, the above method includes a step of applying a side surface scribing process to the original substrate from the top surface of the original substrate and along side surface cutting lines set parallel to the longitudinal direction of the ridges and along the boundaries of the plurality of semiconductor laser devices, and a step of dividing the original substrate along the side surface cutting lines by applying a blade to the original substrate from the rear surface of the original substrate and along the side surface cutting lines.

With the present method, division of the original substrate in relation to the end surface cutting lines orthogonal to the ridge is performed by the scribing process being performed from the rear surface side and the external force being applied from the top surface side. The laser resonance surfaces formed of stable cleavage planes can thereby be formed. Division of the original substrate in relation to the side surface cutting lines parallel to the ridges is performed by the scribing process being performed from the top surface side and the external force being applied from the rear surface side. In regard to the side surface cutting lines, there is no need to avoid the ridge and processing in a continuous pattern is possible even from the top surface side. Division of the original substrate in relation to the side surfaces of the semiconductor laser device can thus be performed with stability.

In a preferred embodiment of the present invention, the side surface scribing step includes a step of applying the scribing process to the original substrate in a continuous manner along the side surface cutting lines. With this method, the division of the original substrate in relation to the side surface cutting lines can be performed with greater stability. To perform the division with further stability, the depth of the scribing process performed in relation to the side surface cutting lines is preferably no less than 80% of the thickness of the original substrate.

Preferred embodiments of the present invention shall now be described in detail with reference to the attached drawings.

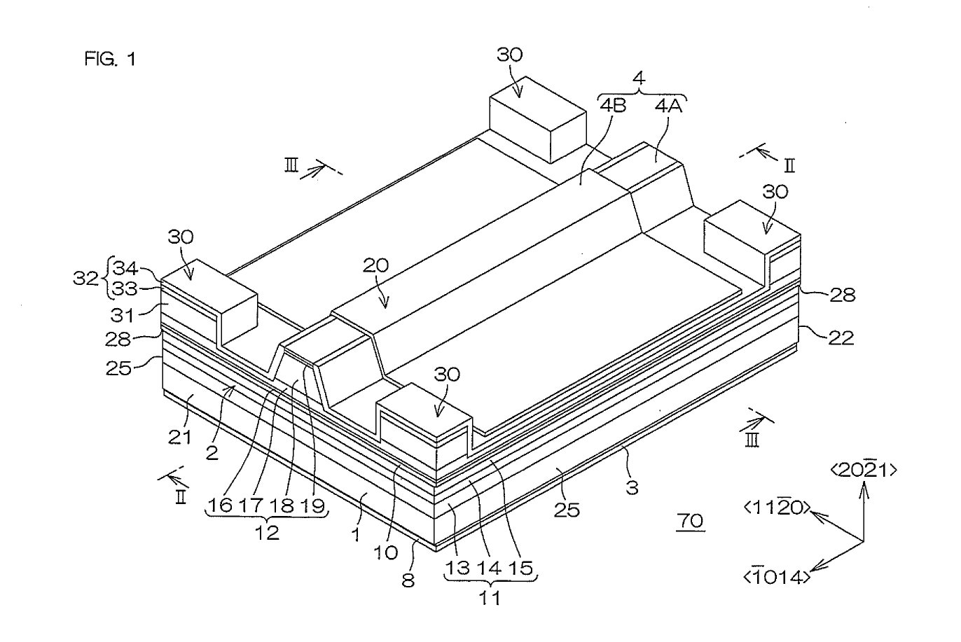

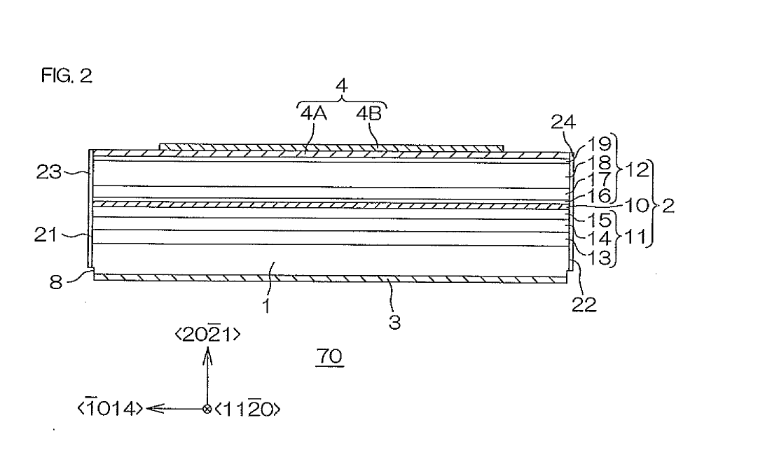

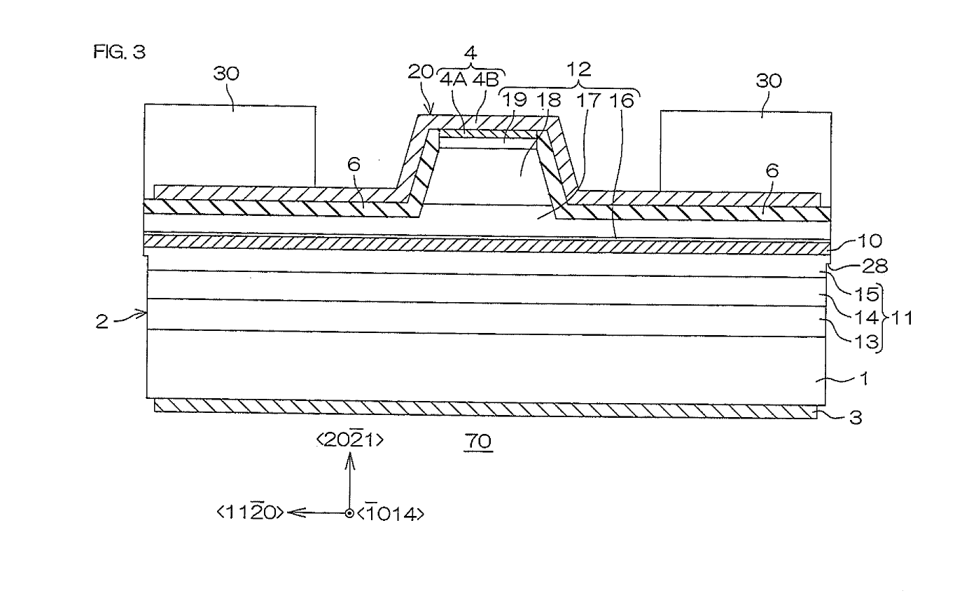

FIG. 1 is a perspective view for describing an arrangement of a semiconductor laser device according to a preferred embodiment of the present invention, FIG. 2 is a longitudinal sectional view taken along the line II-II of FIG. 1, and FIG. 3 is a transverse sectional view taken along the line III-III of FIG. 1.

The semiconductor laser device 70 is a Fabry-Perot type device that includes a substrate 1, a group III nitride semiconductor laminate structure 2 formed by crystal growth on the substrate 1, an n-side electrode 3 as a rear surface electrode that is formed so as to contact a rear surface (surface at opposite side with respect to the group III nitride semiconductor laminate structure 2) of the substrate 1, and a p-side electrode 4 as a top surface electrode formed so as to contact a top surface of the group III nitride semiconductor laminate structure 2. The p-side electrode 4 includes a p-side ohmic electrode 4A and a p-side pad electrode 4B. In the present preferred embodiment, a semiconductor laminate structure that makes up a semiconductor laser diode structure is formed by the substrate 1 and the group III nitride semiconductor laminate structure 2.

In the present preferred embodiment, the substrate 1 is made of a GaN monocrystalline substrate. In the present preferred embodiment, the substrate 1 has a {20-21} plane, which is one of semipolar planes, as a major surface, and the group III nitride semiconductor laminate structure 2 is formed by crystal growth on the major surface. The group III nitride semiconductor laminate structure 2 is thus made of a group III nitride semiconductor having a {20-21} plane as a crystal growth surface (major surface).

Respective layers forming the group III nitride semiconductor laminate structure 2 are grown coherently with respect to the substrate 1. Coherent growth refers to crystal growth in a state of maintaining lattice continuity from a base layer. Lattice mismatch with respect to the base layer is absorbed by lattice strain in crystal-grown layers and the lattice continuity at an interface with the base layer is maintained.

GaN has an a-axis lattice constant of 3.189 Å and a c-axis lattice constant of 5.185 Å. In a strain-free state, AlN has an a-axis lattice constant of 3.112 Å and a c-axis lattice constant of 4.982 Å. The a-axis lattice constant and the c-axis lattice constant of AlGaN are thus smaller when an Al composition is larger. In regard to rate of increase with respect to increase in the Al composition, that of the c-axis lattice constant is greater than that of the a-axis lattice constant. Thus, when an AlGaN crystal is grown coherently on a GaN substrate, tensile strains (internal stresses) in the c-axis direction and the a-axis direction occur and the tensile strain in the c-axis direction is greater in magnitude.

The group III nitride semiconductor laminate structure 2 includes a light emitting layer 10, an n-type semiconductor layer 11, and a p-type semiconductor layer 12. The n-type semiconductor layer 11 is disposed at the substrate 1 side with respect to the light emitting layer 10, and the p-type semiconductor layer 12 is disposed at the p-side ohmic electrode 4A side with respect to the light emitting layer 10. A double heterojunction is thus formed with the light emitting layer 10 being sandwiched by the n-type semiconductor layer 11 and the p-type semiconductor layer 12. Into the light emitting layer 10, electrons are injected from the n-type semiconductor layer 11 and holes are injected from the p-type semiconductor layer 12. Light is emitted by recombination of the electrons and holes in the light emitting layer 10.

The n-type semiconductor layer 11 is formed by laminating an n-type GaN contact layer 13 (for example of 2 μm thickness), an n-type AlInGaN clad layer 14 (of no more than 1.5 μm thickness and, for example, of 1.0 μm thickness), and an n-type InGaN guide layer 15 (for example of 0.1 μm thickness) in that order from the substrate 1 side. The p-type semiconductor layer 12 is formed by laminating a p-type AlGaN electron blocking layer 16 (for example of 20 nm thickness), a p-type InGaN guide layer 17 (for example of 0.1 μm thickness), a p-type AlInGaN clad layer 18 (of no more than 1.5 μm thickness and, for example, of 0.4 μm thickness), and a p-type GaN contact layer 19 (for example of 0.3 μm thickness) in that order on the light emitting layer 10.

The n-type GaN contact layer 13 and the p-type GaN contact layer 19 are low resistance layers. The p-type GaN contact layer 19 is in ohmic contact with the p-side ohmic electrode 4A. The n-type GaN contact layer 13 is made an n-type semiconductor by doping GaN with a high concentration of, for example, Si as an n-type dopant (at a doping concentration of, for example, 3×10¹⁸ cm⁻³). Also, the p-type GaN contact layer 19 is made a p-type semiconductor by doping a high concentration of, for example, Mg as a p-type dopant (at a doping concentration of, for example, 3×10¹⁹ cm⁻³).

The n-type AlInGaN clad layer 14 and the p-type AlInGaN clad layer 18 provide a light confinement effect of confining light from the light emitting layer 10 therebetween. The n-type AlInGaN clad layer 14 is made an n-type semiconductor by doping AlInGaN with, for example, Si as the n-type dopant (at a doping concentration of, for example, 1×10¹⁸ cm⁻³). Also, the p-type AlInGaN clad layer 18 is made a p-type semiconductor layer by doping, for example, Mg as the p-type dopant (at a doping concentration of, for example, 1×10¹⁹ cm⁻³). The n-type AlInGaN clad layer 14 is wider in band gap than the n-type InGaN guide layer 15, and the p-type AlInGaN clad layer 18 is wider in band gap than the p-type InGaN guide layer 17. Satisfactory confinement can thereby be achieved to realize a semiconductor laser diode of low threshold and high efficiency.

The n-type InGaN guide layer 15 and the p-type InGaN guide layer 17 are semiconductor layers that provide a carrier confinement effect of confining carriers (electrons and holes) in the light emitting layer 10 and, together with the clad layers 14 and 18, form a structure that confines light in the light emitting layer 10. Efficiency of recombination of electrons and holes in the light emitting layer 10 is thereby heightened. The n-type InGaN guide layer 15 is made an n-type semiconductor by doping InGaN with, for example, Si as the n-type dopant (at a doping concentration of, for example, 1×10¹⁸ cm⁻³), and the p-type InGaN guide layer 17 is made a p-type semiconductor by doping InGaN with, for example, Mg as the p-type dopant (at a doping concentration of, for example, 5×10¹⁹ cm⁻³)

The p-type AlGaN electron blocking layer 16 is a p-type semiconductor formed by doping AlGaN with, for example, Mg as the p-type dopant (at a doping concentration of, for example, 5×10¹⁸ cm⁻³), and prevents outflow of electrons from the light emitting layer 10 to improve the efficiency of recombination of electrons and holes.

The light emitting layer 10 has, for example, an MQW (multiple-quantum well) structure that contains InGaN, and is a layer for generating light by recombination of electrons and holes and amplifying the generated light.

The light emitting layer 10 may, for example, have the multiple-quantum well (MQW) structure formed by alternately laminating a quantum well layer (for example of 3 nm thickness) made of an InGaN layer and a barrier layer (for example of 9 nm thickness) made of an AlGaN layer repeatedly for a plurality of times. In this case, the quantum well layer made of InGaN is made comparatively low in band gap by an In composition ratio being set to no less than 5% and the barrier layer made of AlGaN is thereby made comparatively high in band gap. For example, the quantum well layer and the barrier layer are repeatedly laminated alternately for two to seven times, and the light emitting layer with the multiple-quantum well structure is thereby arranged. An emission wavelength corresponds to the band gap of the quantum well layer, and the band gap can be adjusted by adjusting the indium (In) composition ratio. The greater the indium composition ratio, the smaller the band gap and the longer the emission wavelength. In the present preferred embodiment, the emission wavelength is set, for example, to 450 nm to 550 nm (blue to green) by adjusting the In composition in the quantum well layer (InGaN layer). With the multiple-quantum well structure, the number of quantum well layers that contain In is preferably no more than three.

As shown in FIG. 1, etc., a portion of the p-type semiconductor layer 12 is removed to form a rectilinear ridge 20. More specifically, the ridge 20 of substantially trapezoidal shape in transverse sectional view (mesa shape) is formed by portions of the p-type contact layer 19, the p-type AlInGaN clad layer 18, and the p-type InGaN guide layer 17 being removed by etching. The ridge 20 is formed along a direction parallel to a direction of a projection vector resulting from projection of the c-axis onto a crystal growth surface of the group III nitride semiconductor laminate structure 2 (hereinafter, this direction shall be referred to as the “c-axis projection direction”).

Further, at a top surface (major surface at the side at which the ridge 20 is formed) of the group III nitride semiconductor laminate structure 2, four receiving portions 30 are formed at positions at both sides of the ridge 20 that are separated from the ridge 20 in a direction orthogonal to a longitudinal direction of the ridge 20. More specifically, a pair of receiving portions 30 are disposed at both sides of one end of the ridge 20, and another pair of receiving portions 30 are disposed at both sides of the other end of the ridge 20. Each receiving portion 30 includes a base portion 31 made of the p-type semiconductor layer 12 and a thin film portion 32 formed on the base portion 31. As with the ridge 20, the base portion 31 is formed by removal of a portion of the p-type semiconductor layer 12. That is, the base portion 31 of substantially trapezoidal shape in transverse sectional view (mesa shape) is formed by portions of the p-type contact layer 19, the p-type AlInGaN clad layer 18, and the p-type InGaN guide layer 17 being removed by etching. The thin film portion 32 includes insulating films 33 and 34 (insulating layer 6 to be described below) formed on a top surface of the base portion 31.

In the present preferred embodiment, each receiving portion 30 is formed to a rectangular shape in plan view. Each receiving portion 30 is formed so that its length in a width direction (resonator width direction; the a-axis direction in the present preferred embodiment) orthogonal to a longitudinal direction (resonator length direction, the <−1014> direction in the present preferred embodiment) of the ridge 20 is greater than a width of the ridge 20. For example, whereas the width of the ridge 20 is approximately 2.5 μm, the length in the width direction of the receiving portion 30 may be several dozen μm to several hundred μm. Also, each receiving portion 30 is formed so that its length in a direction parallel to the ridge 20 is adequately short in comparison to a length (resonator length) of the ridge 20. For example, whereas the length of the ridge 20 is approximately 600 μm, the length in the resonator length direction of the receiving portion 30 may be approximately several dozen μm. Further, each receiving portion 30 is spaced apart by a predefined distance along the width direction from the ridge 20. The distance between a center in the width direction of the ridge 20 and an end edge at the ridge 20 side of the receiving portion 30 may be approximately several μm to several dozen μm.

The group III nitride semiconductor laminate structure 2 has a pair of end surfaces 21 and 22 (cleavage planes) made of mirror surfaces formed by cleavage at respective ends in the longitudinal direction of the ridge 20. The pair of end surfaces 21 and 22 are mutually parallel and, in the present preferred embodiment, are both perpendicular to the projection vector of the c-axis onto the {20-21} plane (that is, are {−1014} planes). A Fabry-Perot resonator having the end surfaces 21 and 22 as laser resonance surfaces is thus formed by the n-type InGaN guide layer 15, the light emitting layer 10, and the p-type InGaN guide layer 17. That is, the light emitted in the light emitting layer 10 is amplified by stimulated emission while reciprocating between the laser resonance surfaces 21 and 22. A portion of the amplified light is taken outside the device as laser light from the laser resonance surfaces 21 and 22.

At the laser resonance surfaces 21 and 22, end surface processing marks 8, due to a scribing process performed in forming the laser resonance surfaces 21 and 22 by cleavage, are formed across an entire width direction in lower edge regions at the rear surface side. The lower edge regions are regions that are continuous with the rear surface of the semiconductor laminate structure including the substrate 1 and the group III nitride semiconductor laminate structure 2. Also, the width direction is a direction (resonator width direction) parallel to the crystal growth surface of the group III nitride semiconductor laminate structure 2 and orthogonal to the longitudinal direction of the ridge 20.

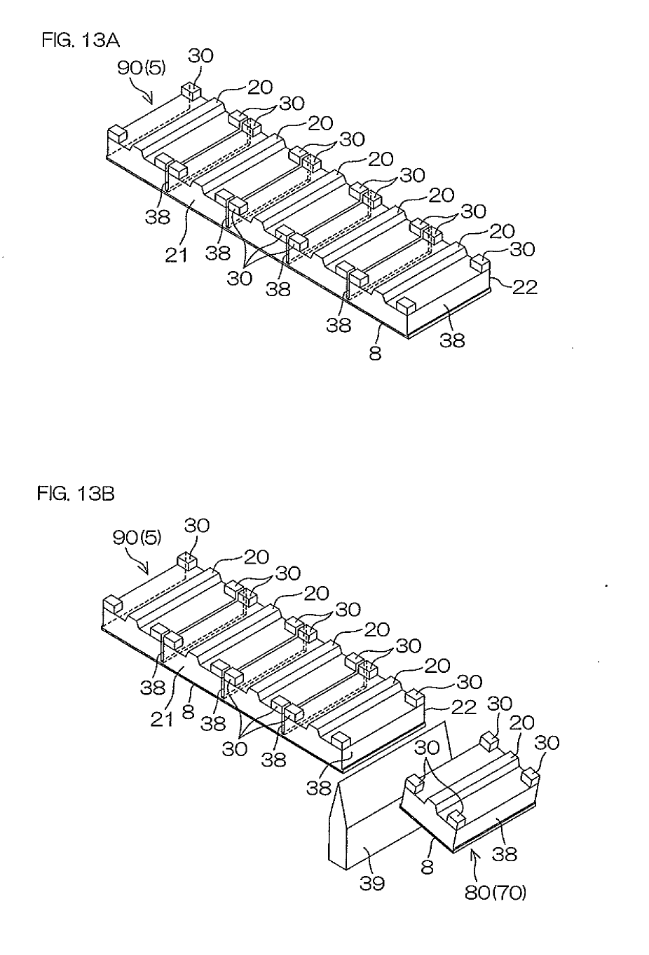

Also, the semiconductor laminate structure including the substrate 1 and the group III nitride semiconductor laminate structure 2 has a pair of side surfaces 25 parallel to the ridge 20. At the pair of side surfaces 25, side surface processing marks 28, due to a scribing process performed in cleaving and dividing the semiconductor laminate structure from the wafer as an original substrate, are formed across an entire length direction. The length direction is a direction (resonator length direction) parallel to the longitudinal direction of the ridge 20. In a case where the scribing process is performed from the rear surface side, the side surface processing marks 28 are formed at lower edge regions of the side surfaces 25 as shown in FIG. 1. In a case where the scribing process is performed from the top surface side, the side surface processing marks 28 are formed in upper edge regions of the side surfaces 25 as shown in FIG. 13B. The upper edge regions are regions that are continuous with the top surface (surface at the ridge 20 side) of the semiconductor laminate structure.

The n-side electrode 3 is made, for example, of Al and is put in ohmic connection with the substrate 1. Also, the p-side ohmic electrode 4A is made, for example, of Pt and is put in ohmic connection with the p-type contact layer 19. An insulating layer 6 that covers exposed surfaces of the p-type InGaN guide layer 17 and the p-type AlInGaN clad layer 18 is disposed so that the p-type ohmic electrode 4A contacts only the p-type GaN contact layer 19 at a topmost surface (band-like contact region) of the ridge 20. Electric current can thereby be made to concentrate in the ridge 20 and efficient laser emission is thus enabled. Also, regions of the top surface of the ridge 20 besides the portion of contact with the p-side ohmic electrode 4A are covered and protected by the insulating layer 6 so that light confinement in a transverse direction is relaxed and easy to control and leak current from side surfaces can be prevented. The insulating layer 6 may be made of an insulating material with a refractive index greater than 1, for example, SiO₂ or ZrO₂. The p-side pad electrode 4B is formed, for example, of Ti/Au.

The insulating layer 6 covers the top surfaces and side surfaces of the receiving portions 30 and portions thereof are arranged as the insulating film 34 that makes up the thin film portions 32. The p-side ohmic electrode 4A is formed in a pattern that exposes the receiving portions 30. More specifically, a predefined interval is opened between each receiving portion 30 and a peripheral edge of the p-side ohmic electrode 4A. The interval may, for example, be approximately 10 μm.

The p-side ohmic electrode 4A contacts the topmost surface of the ridge 20. Each receiving portion 30 has the structure including a base portion 31 of substantially the same height as the ridge 20 and the thin film portion 32, formed by lamination of the insulating films 33 and 34, disposed on the base portion 31. A thickness of the thin film portion 32 is equivalent to or thicker than a thickness of the p-side ohmic electrode 4A. Thus, a height (distance from the top surface of the group III nitride semiconductor laminate structure 2) of the top surface of the receiving portion 30 is equivalent to or higher than a top surface of the p-side ohmic electrode 4A on the ridge 20. The ridge 20 is thereby prevented from receiving a large external stress from a cleaving blade in a dividing step (breaking step) to be described below and the ridge 20 can thus be protected.

The laser resonance surfaces 21 and 22 are covered by insulating films 23 and 24, respectively (omitted from illustration in FIG. 1). The crystal planes of the laser resonance surfaces 21 and 22 are planes perpendicular to the c-axis projection direction and are the {−1014} planes in the present preferred embodiment. The insulating film 23 formed so as to cover the one laser resonance surface 21 is made, for example, of a single film of ZrO₂. The insulating film 24 formed so as to cover the other laser resonance surface 22 is made, for example, of a multiple reflection film in which SiO₂ and ZrO₂ films are alternately laminated repeatedly for a plurality of times. The single film of ZrO₂ that makes up the insulating film 23 has its thickness set to λ/2n₁ (where λ is the emission wavelength of the light emitting layer 10 and n₁ is a refractive index of ZrO₂). The multiple reflection film making up the insulating film 24 has a structure where SiO₂ films with a film thickness of λ/4n₂ (where n₂ is a refractive index of SiO₂) and ZrO₂ films with a film thickness of λ/4n₁ are laminated alternately.

By this structure, the laser resonance surface 21 is made low in reflectance and the laser resonance surface 22 is made high in reflectance. More specifically, the reflectance of the laser resonance surface 21 is set, for example, to approximately 20% and the reflectance of the laser resonance 22 is set to approximately 99.5% (substantially 100%). A larger laser output is thus emitted from the laser resonance surface 21. That is, with the semiconductor laser device 70, the laser resonance surface 21 is used as a laser emitting end surface.

With the above structure, by connecting the n-side electrode 3 and the p-side electrode 4 to a power supply and thereby injecting electrons and holes into the light emitting layer 10 from the n-type semiconductor layer 11 and the p-type semiconductor layer 12, recombination of the electrons and holes can be made to occur to cause emission of light of 450 nm to 550 nm inside the light emitting layer 10. The light is amplified by stimulated emission while reciprocating between the laser resonance surfaces 21 and 22 along the guide layers 15 and 16. A larger laser output is then taken out to the exterior from the laser resonance surface 21 that is the laser emitting end surface.

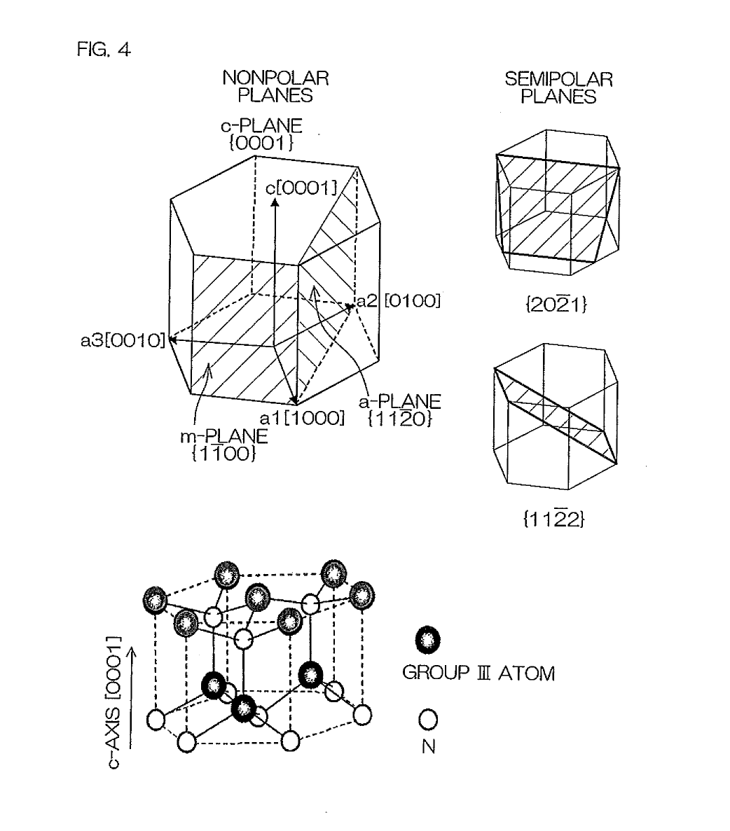

FIG. 4 is a diagrammatic view of a unit cell of a crystal structure of a group III nitride semiconductor. The crystal structure of the group III nitride semiconductor can be approximated by a hexagonal system and four nitrogen atoms are bonded to a single group III atom. The four nitrogen atoms are positioned at four apexes of a regular tetrahedron with the group III atom disposed at a center. With the four nitrogen atoms, one nitrogen atom is positioned at a +c-axis direction with respect to the group III atom and the other three nitrogen atoms are positioned at a −c-axis side with respect to the group III atom. Due to such a structure, a polarization direction lies along the c-axis in the group III nitride semiconductor.

The c-axis lies along an axial direction of a hexagonal prism and a-plane having the c-axis as a normal (top plane of the hexagonal prism) is a c-plane {0001}. When the crystal of the group III nitride semiconductor is cleaved at two planes parallel to the c-plane, a-plane at the +c-axis side (+c-plane) is a crystal plane in which the group III atoms are aligned and a-plane at the −c-axis side (−c-plane) is a crystal plane in which the nitrogen atoms are aligned. The c-plane thus exhibits different properties at the +c-axis side and the −c-axis side and is thus called a polar plane.

Each side plane of the hexagonal prism is an m-plane {1-100} and a plane passing through a pair of non-adjacent ridgelines is an a-plane {11-20}. These are crystal planes perpendicular to the c-plane and are orthogonal to the polarization direction and are thus planes without polarity, in other words, nonpolar planes.

Further, a crystal plane that is inclined with respect to (that is neither parallel nor perpendicular to) the c-plane intersects the polarization direction obliquely and is thus a plane with some polarity, in other words, a semipolar plane. Specific examples of semipolar planes include the {20-21} plane, {11-22} plane, {01-12} plane, {10-1-1} plane, {10-1-3} plane, {11-24} plane, {10-12} plane, etc. Of these, the {20-21} plane and the {11-22} plane are shown in FIG. 4.

For example, a GaN monocrystalline substrate having the {20-21} plane as a major surface can be prepared by cutting out from a GaN monocrystal having the c-plane as a major surface. The {20-21} plane of the substrate that has been cut out is polished, for example, by chemical-mechanical-polishing so that azimuth errors in both the <−1014> direction, which is the c-axis projection direction, and the <11-20> direction orthogonal thereto are within ±1° (preferably within ±0.3°). A GaN monocrystalline substrate having the {20-21} plane as the major surface and is without any crystal defects, such as dislocations and stacking faults, is thereby obtained.

The group III nitride semiconductor laminate structure 2 that makes up the semiconductor laser diode structure is grown by a metal organic chemical vapor deposition method on the GaN monocrystalline substrate thus obtained.

The group III nitride semiconductor that is grown as a crystal on the GaN monocrystalline substrate having the {20-21} plane as the major surface grows with the {20-21} plane as the crystal growth surface. In a case where crystal growth is performed with the c-plane as the major surface, the emission efficiency in the light emitting layer 10 may be poor due to influence of polarization in the c-axis direction. On the other hand, if the {20-21} plane, which is a semipolar plane, is used as the major crystal growth surface, polarization in the quantum well layer is suppressed and the emission efficiency increases. Lowering in the threshold and increase in slope efficiency can thereby be realized. Also, due to the low polarization, current dependence of the emission wavelength is suppressed and a stable emission wavelength can be realized. Further, the In composition of the light emitting layer 10 can be made higher than in a case where the m-plane is used as the major growth surface and elongation of wavelength is enabled.

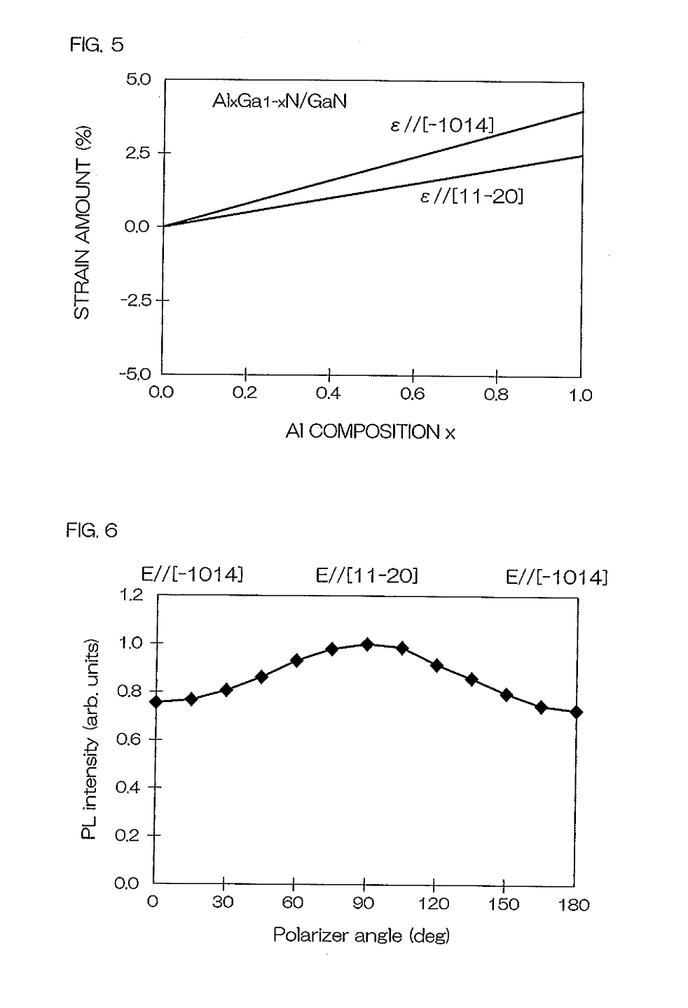

FIG. 5 shows a strain amount (%) of an AlₓGa₁₋ₓN layer (where 0≦x≦1) grown coherently on a GaN monocrystal substrate having the {20-21} plane as the major surface. Variation of the strain amount with respect to aluminum composition x is shown in FIG. 5. The strain amount ε∥[−1014] in the <−1014> direction, which is the c-axis projection direction, and the strain amount ε∥[11-20] in the orthogonal <11-20> direction are both positive in value. Thus, a tensile stress arises in the AlₓGa₁₋ₓN layer. The tensile stress increases with an increase in the aluminum composition x. As is clearly shown in FIG. 5, ε∥[−1014]>ε∥[11-20]. That is, the strain amount ε∥[−1014] in the <−1014> direction that is the c-axis projection direction is greater than the strain amount ε∥[11-20] in the orthogonal <11-20> direction. This means that cleavage in the crystal plane orthogonal to the <−1014> direction is easier than cleavage in the crystal plane orthogonal to the <11-20> direction.

Thus, in the present preferred embodiment, the laser resonance surfaces 21 and 22 are defined by the {−1014} planes orthogonal to the <−1014> direction, which is the c-axis projection direction. The laser resonance surfaces 21 and 22 made of cleavage planes of satisfactory flatness are thus obtained by cleaving the original substrate, with which the group III nitride semiconductor laminate structure 2 has been grown on the substrate 1, at the {−1014} planes.

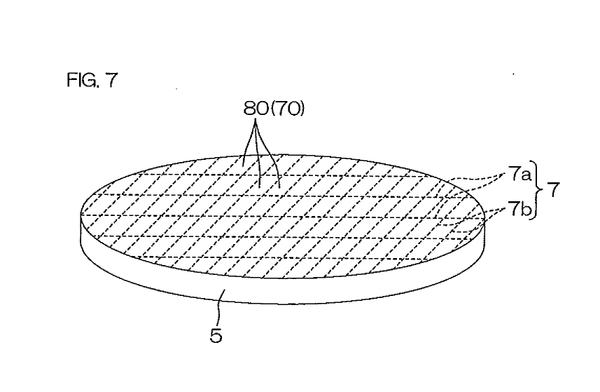

FIG. 6 shows results of measuring PL (photoluminescence) polarization characteristics of a group III nitride semiconductor (sample) grown with the {20-21} plane as the crystal growth surface. Specifically, laser light from an excitation light source was irradiated onto the sample to cause photoluminescence to occur and the emitted light was passed through a polarizer and detected by a CCD spectrometer. An abscissa of FIG. 6 indicates a polarizer angle that was varied within a-plane parallel to the {20-21} plane. When the polarizer angle is 0 degrees or 180 degrees, the polarizer transmits a polarization component in the <−1014> direction (polarization component with an electric field E parallel to the <−1014> direction). When the polarizer angle is 90 degrees, the polarizer transmits a polarization component in the <11-20> direction (polarization component with the electric field E parallel to the <11-20> direction). An ordinate indicates a photoluminescence intensity (PL intensity (arbitrary units)).

FIG. 6 shows that the polarization component in the <11-20> direction, which is the a-axis projection direction, is strongest in intensity. Thus, by setting the resonator length direction (longitudinal direction of the ridge 20) to the <−1014> direction, which is the c-axis projection direction, the polarization component of the strongest intensity will be orthogonal thereto. Consequently, TE mode light can be used with high efficiency and the emission efficiency can be improved.

A method for manufacturing the semiconductor laser device 70 shall now be described.

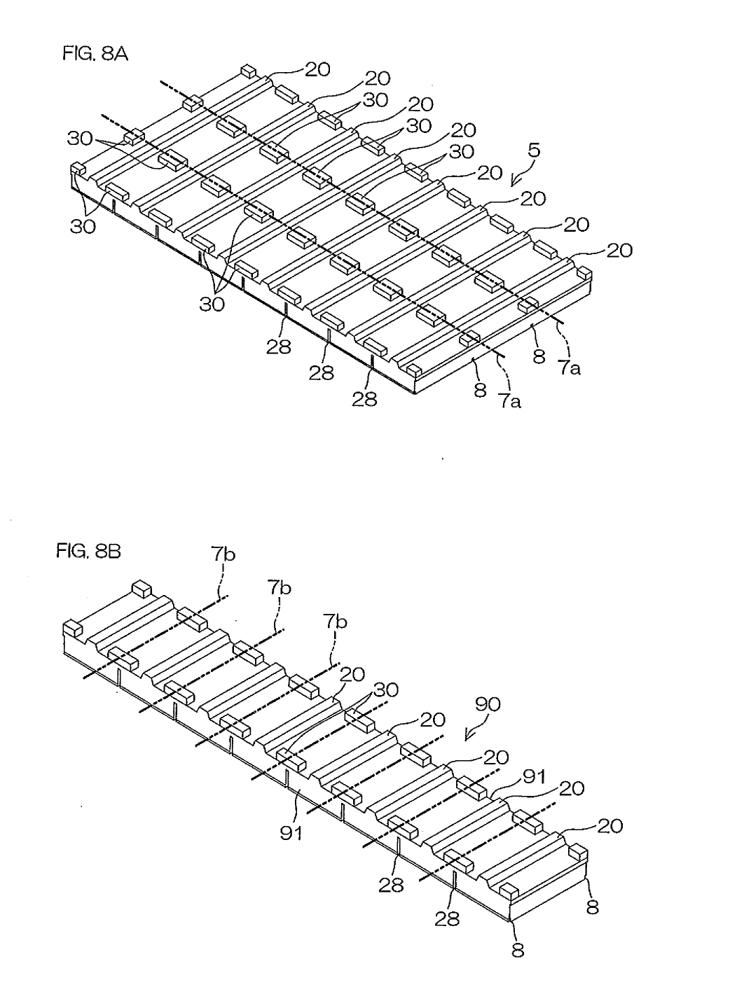

To manufacture the semiconductor laser device 70, first, as shown diagrammatically in FIG. 7, a plurality of individual devices 80 (semiconductor laser device regions) that respectively make up the semiconductor laser devices 70 are formed in an array on a wafer 5, which is an original substrate that makes up the group III nitride semiconductor substrate 1 made of the GaN monocrystalline substrate.

More specifically, the n-type semiconductor layer 11, the light emitting layer 10, and the p-type semiconductor layer 12 are grown epitaxially on the wafer 5 (in the state of the GaN monocrystalline substrate) to form the group III nitride semiconductor laminate structure 2.

After the group III nitride semiconductor laminate structure 2 has been formed, the ridges 20 and the base portions 31 (portions of the receiving portions 30) are formed, for example, by dry etching. Before the dry etching, the insulating film 33 (for example, a silicon oxide film) is selectively formed as a hard mask for dry etching at the regions at which the ridges 20 and the base portions 31 are formed. The insulating film 33 is removed selectively after the dry etching. Specifically, the insulating film 33 is left on the base portions 31 and the insulating film 33 on the topmost surfaces of the ridges 20 is removed. The topmost surfaces of the ridges 20 are thereby exposed while the insulating film 33, which is the first layer making up the thin film portions 32, is formed on the base portions 31.

Next, the insulating layer 6, made, for example, of silicon oxide, is formed on an entire surface and the insulating layer 6 on the topmost surfaces of the ridges 20 is removed. The insulating layer 34 (insulating layer 6) that is the second layer is thereby formed on the insulating film 33 at the base portions 31.

Thereafter, the p-side ohmic electrodes 4A, the p-side pad electrodes 4B, and the n-side electrodes 3 are formed. The p-side ohmic electrodes 4A and the p-side pad electrodes 4B are formed by patterning at portions besides the receiving portions 30 and regions peripheral thereto. The p-side ohmic electrodes 4A and the p-side pad electrodes 4B are thereby arranged so as not to cover the receiving portions 30 at all and the peripheral edges of the p-side electrodes 4 are positioned across intervals from the receiving portions 30. The forming of the p-side electrodes 4 may be performed, for example, by a metal vapor deposition apparatus that uses resistance heating or an electron beam.

The wafer 5 in the state where the plurality of individual devices 80 are formed is thereby obtained. If necessary, a grinding/polishing process (for example, chemical-mechanical-polishing) is performed from a rear surface side of the wafer 5 to make the wafer 5 thin before the n-side electrodes 3 are formed.

The respective individual devices 80 are formed in respective rectangular regions defined by grid-like cutting lines 7 (virtual lines) that are assumed on the wafer 5. The cutting lines 7 include end surface cutting lines 7a lying along the resonator width direction (the <11-20> direction that is the a-axis projection direction) and side surface cutting lines 7b lying along the resonator length direction (the <−1014> direction that is the c-axis projection direction).

The wafer 5 is divided into the respective individual devices 80 along such cutting lines. That is, the individual devices 80 are cut out by cleaving the wafer 5 along the cutting lines 7.

A method for dividing the wafer 5 into the individual devices 80 shall now be described specifically.

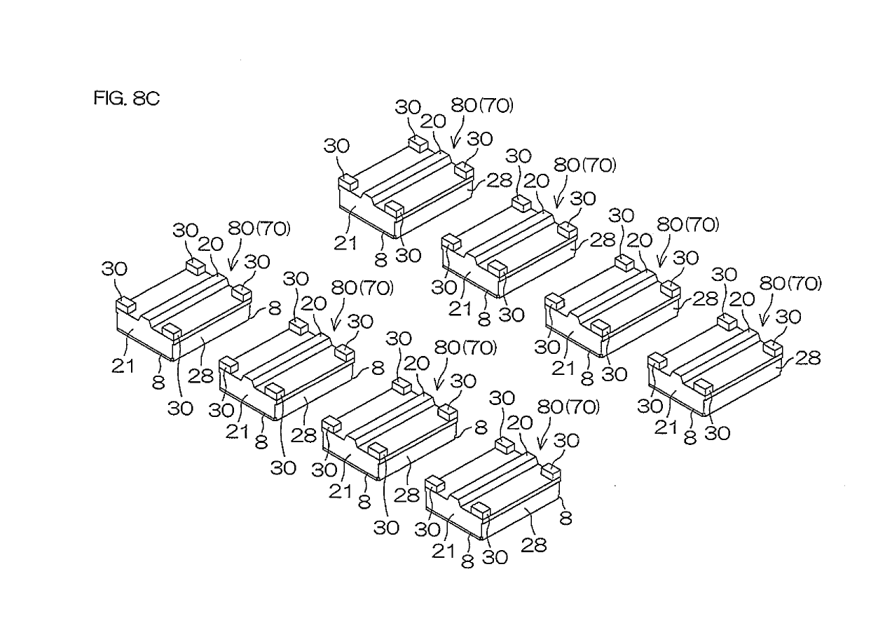

Each of FIG. 8A, FIG. 8B, and FIG. 8C is a diagrammatic perspective view for describing, in outline, a procedure for dividing the wafer 5 into the individual devices 80. The wafer 5 is first cleaved along the end surface cutting lines 7a that are orthogonal to the resonator length direction (c-axis projection direction) (that is, parallel to the {−1014} planes). This shall be referred to hereinafter as “primary cleavage.” By the primary cleavage, a plurality of bar-like bodies 90 shown in FIG. 8B are obtained. Respective side surfaces 91 of each bar-like body 90 are crystal planes that become the laser resonance surfaces 21 and 22. The insulating films 23 and 24 (end surface coating films for reflectance adjustment; see FIG. 2) are formed on the side surfaces 91 of the bar-like bodies.

Next, the respective bar-like bodies 90 are cut along the side surface cutting lines 7b parallel to the resonator length direction (c-axis projection direction). This shall be referred to hereinafter as “secondary cleavage.” By the secondary cleavage, the bar-like bodies 90 are divided according to the individual devices 80 and a plurality of chips are obtained as shown in FIG. 8C.

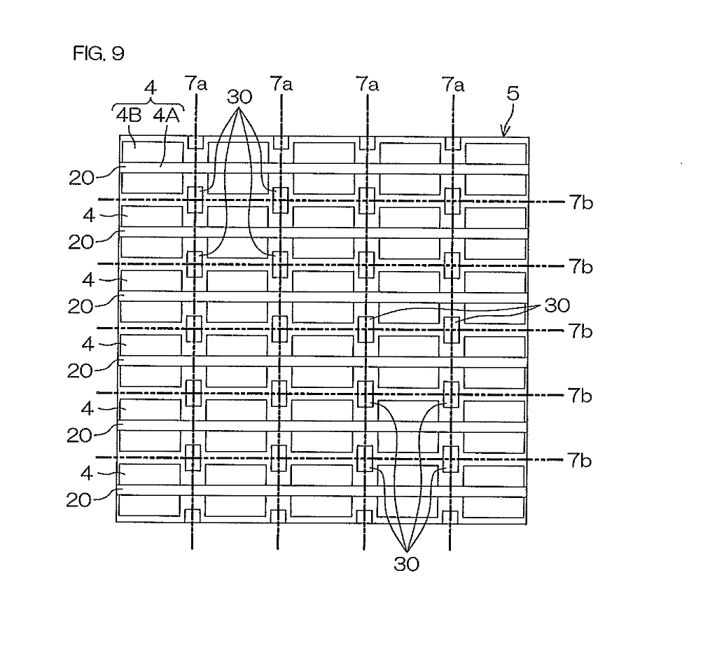

FIG. 9 is a partially enlarged plan view for describing positioning of the p-side electrodes 4 and the receiving portions 30 on the top surface of the wafer 5. The plurality of ridges 20 are formed in stripes on the wafer 5. That is, the plurality of ridges 20 are formed parallel to each other across fixed intervals. Each ridge 20 is formed so as to pass through a plurality of the individual devices 80 that are aligned in one direction. The end surface cutting lines 7a are set along a direction orthogonal to each ridge 20. The end surface cutting lines 7a are set at intervals that extend along a direction parallel to the ridge 20 (resonator length direction) and are equal to the resonator length.

At both sides of each ridge stripe 20, the receiving portions 30 that are substantially rectangular in plan view are formed in regions near the end surface cutting lines 7a so as to cross the end surface cutting lines 7a. The side surface cutting lines 7b are set parallel to the ridges 20 at intermediate positions substantially equidistant from mutually adjacent ridges 20. The receiving portions 30 are formed across regions that cross the side surface cutting lines 7b. That is, four receiving portions 30, respectively belonging to four individual devices 80 that share an intersection of an end surface cutting line 7a and a side surface cutting line 7b, are formed integrally on the top surface of the wafer 5 before cutting.

Each p-side ohmic electrode 4A is formed across the entire topmost surface of the ridge 20. At regions besides the topmost surfaces of the ridges 20, the p-side electrodes 4 are formed in band-like patterns in which width-direction peripheral edges are disposed at positions recessed by a predefined distance from the side surface cutting lines 7b. Further, in regard to the longitudinal direction of the ridges 20, the p-side electrodes 4 are formed in narrow-width band-like patterns in regions corresponding to the receiving portions 30 and avoid the receiving portions 30. More specifically, in these regions, the p-side ohmic electrodes 4A are formed only near the topmost surfaces of the ridges 20 and the p-side pad electrodes 4B are not formed.

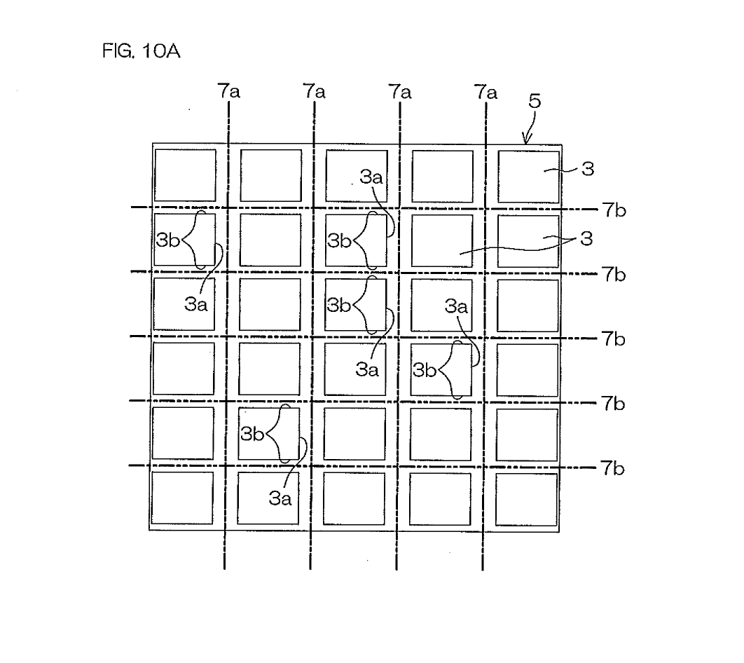

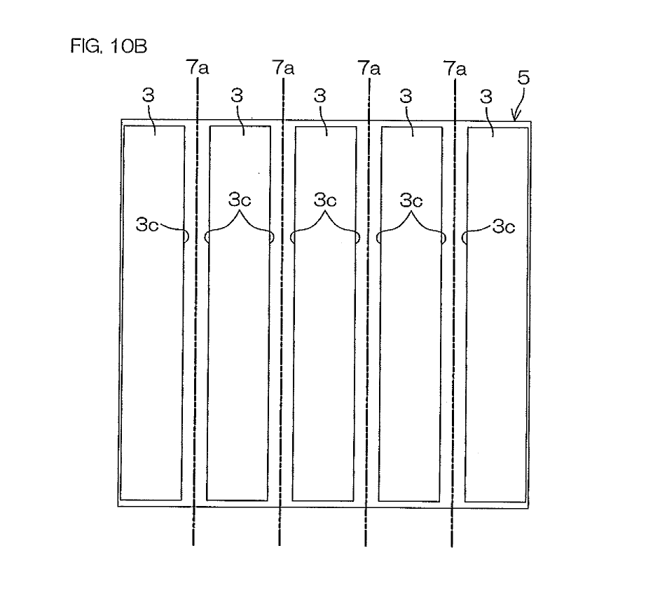

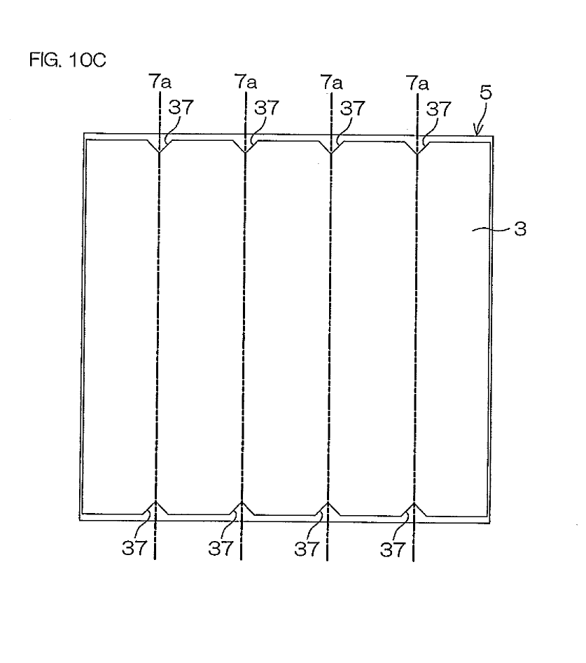

FIG. 10A is a bottom view of a first formation pattern example of the n-side electrodes 3. In the present example, the n-side electrodes 3 are formed in rectangular patterns respectively in a plurality of rectangular regions defined by the cutting lines 7a and 7b. Each individual n-side electrode 3 has peripheral edges that are recessed by predefined distances from both the end surface cutting lines 7a and the side surface cutting lines 7b. More specifically, each individual n-side electrode 3 has, at its peripheral edges, end surface recessed portions 3a that are recessed from the end surface cutting lines 7a corresponding to the laser resonance surfaces 21 and 22 of the semiconductor laser device 70 and side surface recessed portions 3b that face the side surface cutting lines 7b corresponding to the side surfaces 25 of the semiconductor laser device 70. The end surface recessed portions 3a are formed rectilinearly in parallel to the end surface cutting lines 7a, and the side surface recessed portions 3b are formed rectilinearly in parallel to the side surface cutting lines 7b. Thus, portions at which the plurality of n-side electrodes 3 are not formed form thin line-like regions matching the cutting lines 7a and 7b. Processing necessary for cutting the wafer 5 can thus be performed using the line-like regions as guide marks.

FIG. 10B is a bottom view of a second formation pattern example of the n-side electrodes 3. In the present example, the n-side electrodes 3 are formed in band-like patterns respectively inside a plurality of band-like regions defined by the end surface cutting lines 7a. The n-side electrodes 3 in the present example are not separated by the side surface cutting lines 7b. Each individual n-side electrode 3 has, at its peripheral edges, end surface recessed portions 3c that are recessed by predefined distances from the end surface cutting lines 7a corresponding to the laser resonance surfaces 21 and 22 of the semiconductor laser device 70. The end surface recessed portions 3c are formed to rectilinear shapes parallel to the end surface cutting lines 7a. Thus, portions at which the n-side electrodes 3 are not formed form thin, line-like regions matching the end surface cutting lines 7a. The processing necessary for cutting the wafer 5 can thus be performed using the line-like regions as guide marks.

FIG. 10C is a bottom view of a third formation pattern example of the n-side electrodes 3. In the present example, the n-side electrodes 3 have a pair of notches 37 at both ends of each end surface cutting line 7a. Each notch 37 has a shape that is recessed toward an inner side of the n-side electrode 3. In the present example, the n-side electrodes 3 are not separated by the cutting lines 7a and 7b. A straight line passing through a pair of notches 37 that oppose each other along a direction orthogonal to the ridge 20 matches the end surface cutting line 7a. The processing necessary for cutting the wafer 5 can thus be performed using the notches 37 as guide marks.

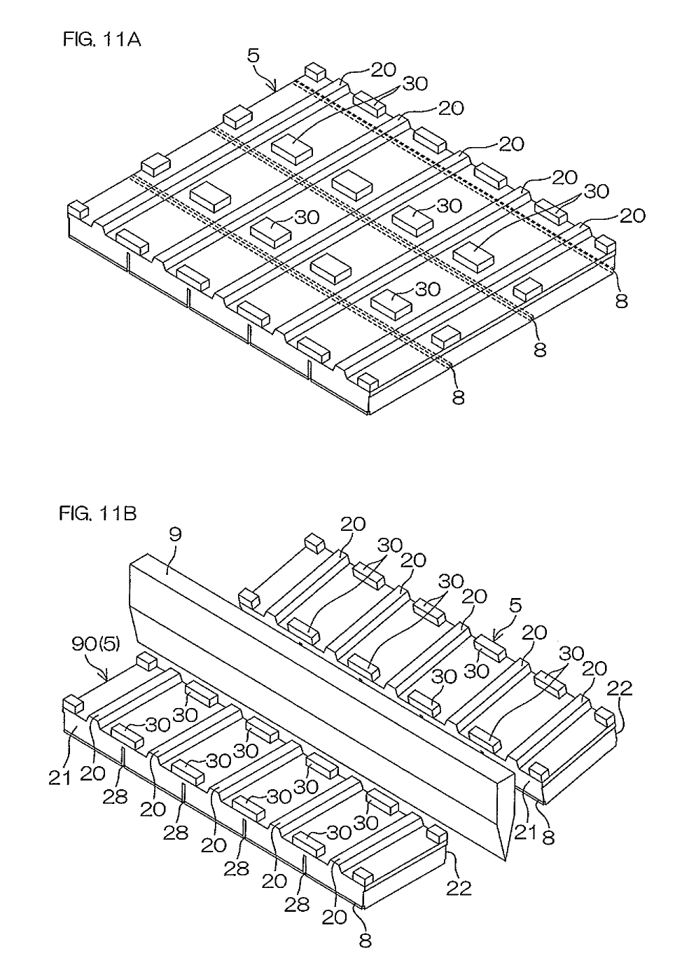

FIG. 11A and FIG. 11B are explanatory diagrams for describing a specific example of the primary cleavage. The primary cleavage includes a rear surface scribing step shown in FIG. 11A and a top surface breaking step shown in FIG. 11B.

As shown in FIG. 11A, in the rear surface scribing step, a scribing process is applied along the end surface cutting lines 7a from the rear surface of the wafer 5. The top surface of the wafer 5 is the major surface on which the ridges 20 are formed and the major surface at the opposite side is the rear surface of the wafer 5. The scribing process may be performed by a laser beam machine (laser scriber) or by a diamond scriber. By the scribing process, end surface processing marks 8 that are continuous along the end surface cutting lines 7a are formed on the rear surface side of the wafer 5. The end surface processing marks 8 are continuous across the entire width directions of the laser resonance surfaces 21 and 22 in each individual device 80 (semiconductor laser device 70). The end surface processing marks 8 may be of groove shapes (dividing guide grooves). A depth of the scribing process is preferably no less than 10% of a thickness of the wafer 5 at the end surface cutting lines 7a (to be more accurate, a thickness of the semiconductor laminate structure including the substrate 1 and the group III nitride semiconductor laminate structure 2). Thus, each end surface processing mark 8 is formed in a lower edge region extending from the rear surface of the wafer 5 (the substrate 1 and the group III nitride semiconductor laminate structure 2) to a depth range no less than 10% of the thickness of the wafer 5.

As shown in FIG. 11B, in the top surface breaking step, an external force is applied to the wafer 5 while applying a blade 9 (for example, a ceramic blade) along each end surface cutting line 7a from the top surface side of the wafer 5. The wafer 5 is thereby cleaved along the end surface processing marks 8 at crystal planes perpendicular to the major surfaces of the wafer 5. The laser resonance surfaces 21 and 22 made of the cleavage planes perpendicular to the ridges 20 are thereby obtained. Each of the laser resonance surfaces 21 and 22 will thus have the end surface processing mark 8 at the lower edge region at the rear surface side. The end surface processing mark 8 may, for example, have a shape in which a linear groove is split in half along a longitudinal direction (partial groove-like shape).

When the blade 9 is applied to the wafer 5, an edge of the blade 9 contacts the receiving portions 30 and a large portion of the external force from the blade 9 is received by the receiving portions 30. This is so because the height of each receiving portion 30 is no less than the height of the ridge 20 (to be more accurate, a height of the p-side ohmic electrode 4A formed on the topmost surface) and the length of each receiving portion 30 in a direction along the blade 9 is greater than the width of the ridge 20. Thus, when the external force is applied to the wafer 5 by the blade 9, most (or all) of the external force is received by the receiving portions 30 and the external force hardly acts (or does not act at all) on the ridges 20. The breaking process using the blade 9 can thus be performed while protecting the ridge 20 from the external force. The primary cleavage can thus be performed without flawing the waveguide and a satisfactory yield is thus attained.

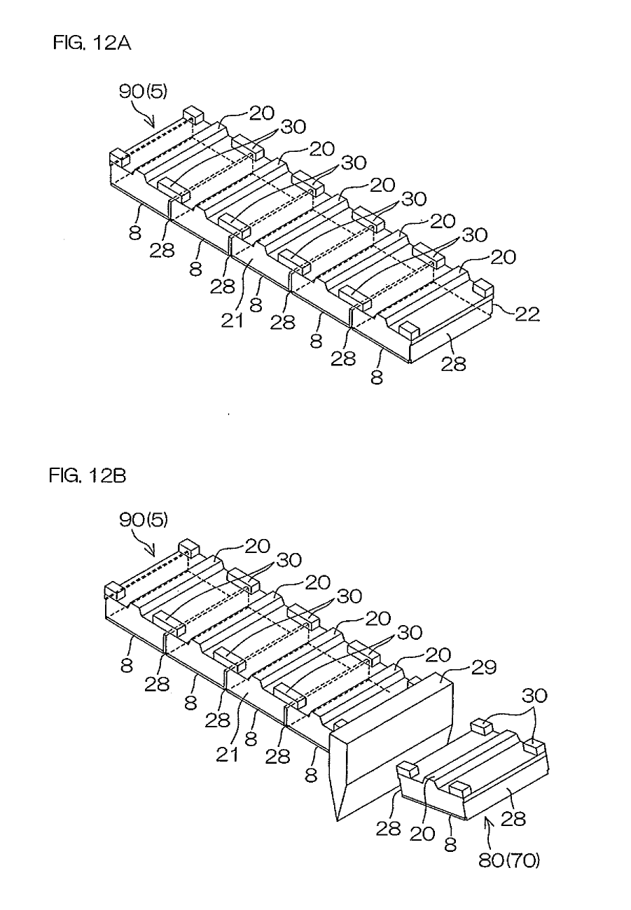

FIG. 12A and FIG. 12B are explanatory diagrams for describing a specific example of the secondary cleavage. The secondary cleavage in the present specific example includes a rear surface scribing step shown in FIG. 12A and a top surface breaking step shown in FIG. 12B.

As shown in FIG. 12A, in the rear surface scribing step, a scribing process is applied along the side surface cutting lines 7b from the rear surface of the wafer 5. The scribing process is preferably performed before the breaking step of the primary cleavage, and may be performed before or after the scribing process of the primary cleavage (scribing process along the end surface cutting lines 7a). The scribing process may be performed by a laser beam machine (laser scriber) or by a diamond scriber, and preferably the same processing method as that of the scribing process of the first cleavage is applied. By the scribing process, side surface processing marks 28 are formed along the side surface cutting lines 7b at the rear surface side of the wafer 5. The side surface processing marks 28 may be of groove shapes (dividing guide grooves). The depth of the scribing process is preferably no less than 80% of the thickness of the wafer 5 at the side surface cutting lines 7b (to be more accurate, the total thickness of the substrate 1 and the group III nitride semiconductor laminate structure 2 at portions besides the ridges 20 and the receiving portions 30). Thus, each side surface processing mark 28 is formed in a lower edge region extending from the rear surface of the wafer 5 (the semiconductor laminate structure including the substrate 1 and the group III nitride semiconductor laminate structure 2) to a depth range no less than 80% of the thickness of the wafer 5.

As shown in FIG. 12B, the top surface breaking step is performed after the breaking step in the primary cleavage. Thus, in the top surface breaking step in the secondary cleavage, an external force is applied to the wafer 5 (bar-like body 80) while applying a blade 29 (for example, a ceramic blade) along each side surface cutting line 7b from the top surface side of the bar-like body 80 obtained by the primary cleavage. The wafer 5 (bar-like body 80) is thereby cleaved along the side surface processing marks 28 at crystal planes perpendicular to the major surfaces of the wafer 5. The side surfaces 25 parallel to the ridges 20 are thereby formed. Each of the side surfaces 25 will have the side surface processing mark 28 at the lower edge region at the rear surface side. The side surface processing mark 28 may, for example, have a shape in which a linear groove is split in half along a longitudinal direction (partial groove-like shape).

When the blade 29 is applied to the wafer 5 (bar-like body 80), an edge of the blade 29 contacts the receiving portions 30. This is so because the height of each receiving portion 30 is higher than the height of the p-side ohmic electrode 4A. Thus, when the external force is applied to the wafer 5 (bar-like body 80) by the blade 29, the external force is initially received by the receiving portions 30. The cleavage thus begins from the receiving portions 30 and the cleavage range spreads to the entire resonator length direction of the bar-like body 80. Cleavage related to the side surfaces parallel to the ridges 20 can thereby be performed with stability as well.

FIG. 13A and FIG. 13B are explanatory diagrams for describing another specific example of the secondary cleavage. The secondary cleavage in the present specific example includes a top surface scribing step shown in FIG. 13A and a rear surface breaking step shown in FIG. 13B.

As shown in FIG. 13A, in the top surface scribing step, a scribing process is applied along the side surface cutting lines 7b from the top surface of the wafer 5. The scribing process is preferably performed before the breaking step of the primary cleavage, and may be performed before or after the scribing process of the primary cleavage (scribing process along the end surface cutting lines 7a). The scribing process may be performed by a laser beam machine (laser scriber) or by a diamond scriber. By the scribing process, side surface processing marks 38 are formed along the side surface cutting lines 7b at the top surface side of the wafer 5. The side surface processing marks 38 may be of groove shapes (dividing guide grooves). The depth of the scribing process is preferably no less than 80% of the thickness of the wafer 5 at the side surface cutting lines 7b (to be more accurate, the total thickness of the substrate 1 and the group III nitride semiconductor laminate structure 2 at portions besides the ridges 20 and the receiving portions 30). Thus, each side surface processing mark 38 is formed in an upper edge region extending from the top surface of the wafer 5 (the semiconductor laminate structure including the substrate 1 and the group III nitride semiconductor laminate structure 2) to a depth range no less than 80% of the thickness of the wafer 5.

As shown in FIG. 13B, the rear surface breaking step is performed after the breaking step in the primary cleavage. Thus, in the rear surface breaking step in the secondary cleavage, an external force is applied to the wafer 5 (bar-like body 80) while applying a blade 39 (for example, a ceramic blade) along each side surface cutting line 7b from the rear surface side of the bar-like body 80 obtained by the primary cleavage. The wafer 5 (bar-like body 80) is thereby cleaved along the side surface processing marks 38 at crystal planes perpendicular to the major surfaces of the wafer 5. The side surfaces 25 parallel to the ridges 20 are thereby formed. Each of the side surfaces 25 will thus have the side surface processing mark 38 at the upper edge region at the side surface as shown in FIG. 13B. The side surface processing mark 38 may, for example, have a shape in which a linear groove is split in half along a longitudinal direction (partial groove-like shape).

As described above, in the semiconductor laser device 70 of the present preferred embodiment, the group III nitride semiconductor laminate structure 2 that makes up the semiconductor laser diode structure is grown on the substrate 1 with the {20-21} plane, which is a semipolar plane, as the crystal growth surface. The light emitting layer 10 of high In composition can thus be formed and thus the semiconductor laser device 70 of a green wavelength range can be realized. With the group III nitride semiconductor having the semipolar plane as the major crystal growth surface, influence of an internal electric field is small and thus a semiconductor laser device of high emission efficiency can be realized in the same manner as in a case of a group III nitride semiconductor having the m-plane, which is a nonpolar plane, as the crystal growth surface. Further, the ridge 20 is set parallel to the <−1014> direction, which is the c-axis projection direction, and the {−1014} planes perpendicular to the c-axis projection direction are the laser resonance surfaces 21 and 22. The {−1014} planes are crystal planes that enable cleavage that makes use of the internal stress of the group III nitride semiconductor laminate structure 2 and thus the laser resonance surfaces 21 and 22 that are made of cleavage planes of satisfactory flatness are obtained. Excellent emission efficiency can thereby be realized. Moreover, the semiconductor laser diode structure (group III nitride semiconductor laminate structure 2) that is formed with the {20-21} plane as the major growth surface causes polarization in the <11-20> direction that is orthogonal to the <−1014> direction. By thus setting the resonator length in the <−1014> direction orthogonal to the <11-20> direction, TE mode light can be used with high efficiency and the emission efficiency can be improved further.

Also, with the present preferred embodiment, the semiconductor laminate structure that includes the substrate 1 and the group III nitride semiconductor laminate structure 2 has the end surface processing marks 8 formed in the lower edge regions of the laser resonance surfaces 21 and 22. That is, with the semiconductor laser device 70, the end surface processing marks 8 are formed by applying processing from the rear surface side of the semiconductor laminate structure, the original substrate is cleaved by applying the external force upon applying the blade 9 from the top surface side of the semiconductor laminate structure, and the laser resonance surfaces 21 and 22 can be formed by the cleavage planes. The end surface processing marks 8 are formed at the rear surface side at which the ridges 20 are not formed and can thus be formed in a continuous pattern because there is no need to form the marks in a discontinuous pattern with discontinuous portions near the ridges 20. The cleavage by the external force applied from the top surface side can thus be performed with stability and thus satisfactory cleavage planes can be obtained. The semiconductor laser device 70 of excellent characteristics can thereby be provided. Specifically, reduction in threshold current, increase in slope efficiency, and reduction in operating current, etc., can be achieved.

Also, with the semiconductor laser device 70, the receiving portions 30 are disposed at positions of the top surface of the group III nitride semiconductor laminate structure 2 that are separated from the ridge 20 in the width direction orthogonal to the longitudinal direction of the ridge 20 and the receiving portions 30 have a height no less than that of the ridge 20, has a length in the width direction that is greater than the width of the ridge 20, and are spaced by an interval from the p-side ohmic electrode 4A. Thus, when the external force is applied upon applying the blade 9 to the top surface side of the wafer 5, all or nearly all of the external force can be made to act on the receiving portions 30. The laser resonance surfaces 21 and 22 that are formed of satisfactory cleavage planes can thereby be formed by dividing (cleaving) the wafer 5, which is the original substrate, while protecting the ridge 20. Moreover, each receiving portion 30 has a length in the width direction that is greater than the width of the ridge 20 and can thus receive the external force reliably. Also, the receiving portions 30 are spaced by intervals from the p-side ohmic electrode 4A and thus the p-side ohmic electrode 4A is not flawed when the external force is received. Current leak and other problems will thus not be caused.

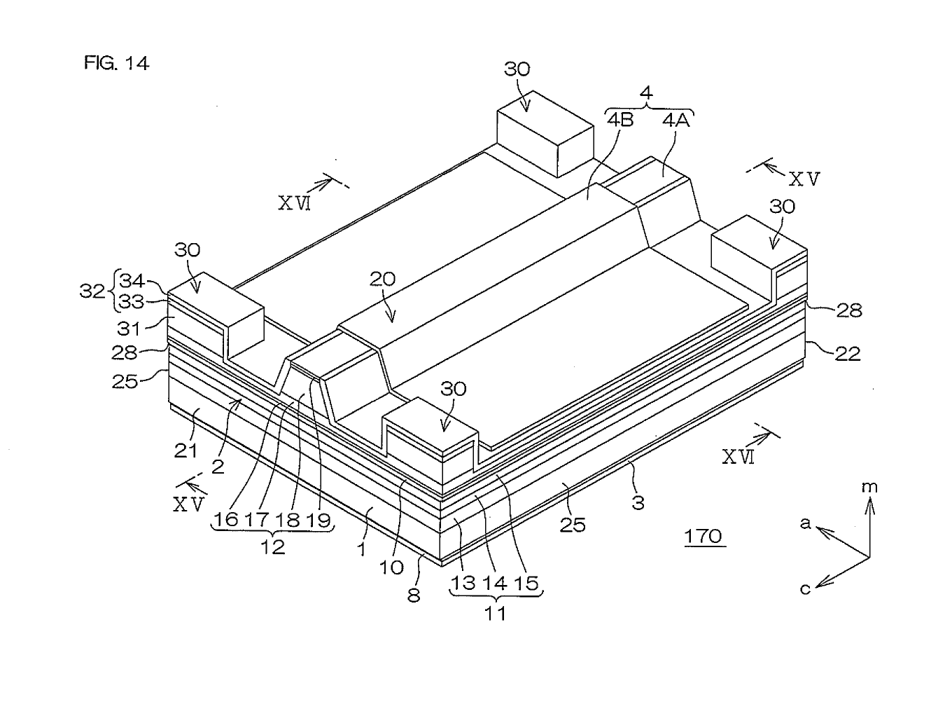

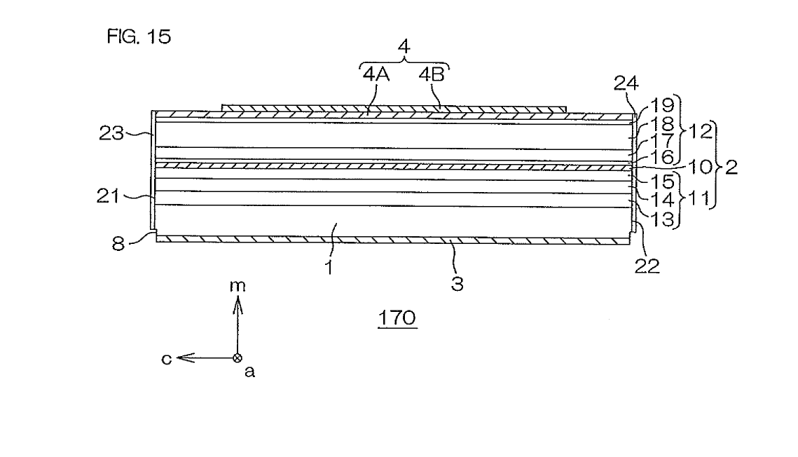

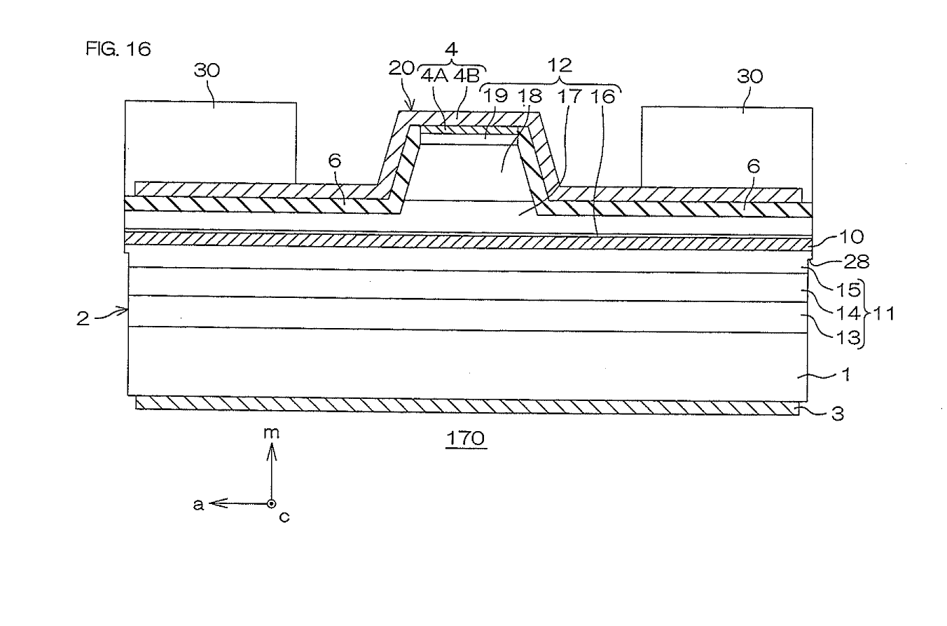

FIG. 14 is a perspective view for describing an arrangement of a semiconductor laser device according to another preferred embodiment of the present invention, FIG. 15 is a longitudinal sectional view taken along the line XV-XV of FIG. 14, and FIG. 16 is a transverse sectional view taken along the line XVI-XVI of FIG. 14. With FIG. 14 to FIG. 16, portions corresponding to the respective portions indicated in FIG. 1 to FIG. 3 described above are provided with the same reference symbols.

In the semiconductor laser device 170 according to the present preferred embodiment, the substrate 1 is made of a GaN monocrystalline substrate, and the m-plane, which is one of the nonpolar planes, is used as the major surface. The group III nitride semiconductor laminate structure 2 is formed by crystal growth on this major surface. The group III nitride semiconductor laminate structure 2 is thus made of the group III nitride semiconductor having the m-plane as the crystal growth surface (major surface).

Also, the ridge 20 is formed along the c-axis direction and the resonator direction defined by the longitudinal direction of the ridge 20 is the c-axis direction. The resonator width direction orthogonal to the resonator direction is the a-axis direction. The resonator end surfaces 21 and 22 are both crystal planes perpendicular to the c-axis, in other words, c-planes. In the present preferred embodiment, the laser resonance surface 21 that is the laser emitting end surface is the +c-axis side end surface (that is, the +c-plane) and the laser resonance surface 22 at the opposite side is the −c-axis side end surface (that is, the −c-plane).

The other arrangements are the same as those of the preferred embodiment shown in FIG. 1, etc., and thus in place of description, the description related to the preferred embodiment shown in FIG. 1, etc., is cited as reference. However, with the wafer 5 of FIG. 7, the end surface cutting lines 7a extend along the a-axis (parallel to the c-plane) and the side surface cutting lines 7b extend along the c-axis (parallel to the a-plane).

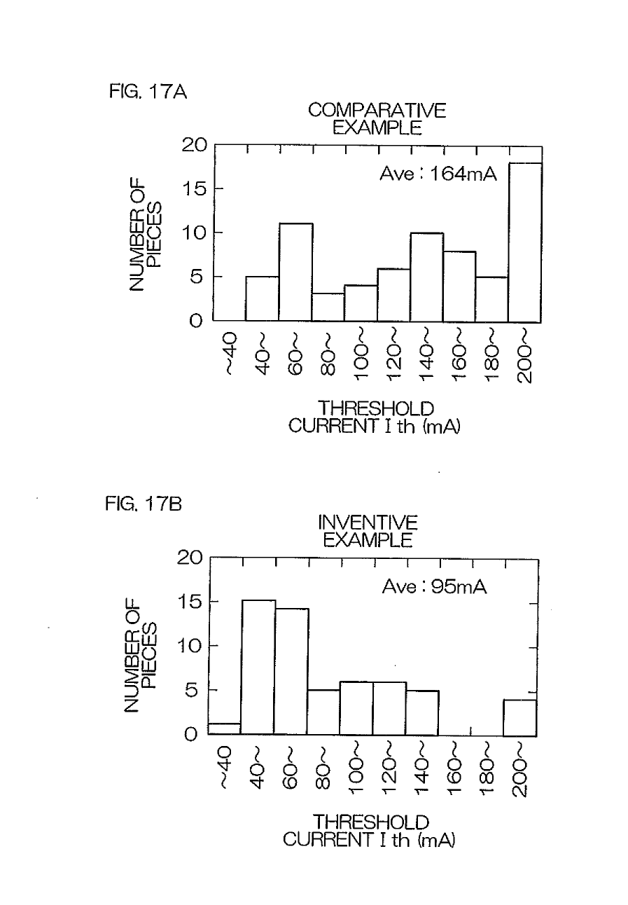

FIG. 17A is a histogram of results of measuring threshold currents Ith of a plurality of samples (semiconductor laser devices) according to a comparative example in which the primary cleavage was performed by performing the scribing step from the top surface side of the wafer 5 and performing the breaking step from the rear surface side. In this case, the scribing step was performed along the end surface cutting line 7a in a perforated, discontinuous pattern that is discontinuous at portions of the ridges 20 so as not to flaw the ridge 20. FIG. 17B is a histogram of results of measuring the threshold currents Ith of a plurality of samples (semiconductor laser devices) according to an inventive example in which the primary cleavage was performed by performing the scribing step from the rear surface side of the wafer 5 and performing the breaking step from the top surface side. As described above, the scribing step was performed in a continuous, line-like manner along the end surface cutting lines 7a. A comparison of FIGS. 17A and 17B shows that in comparison to the comparative example, the threshold current Ith is reduced by approximately 40% in the inventive example.

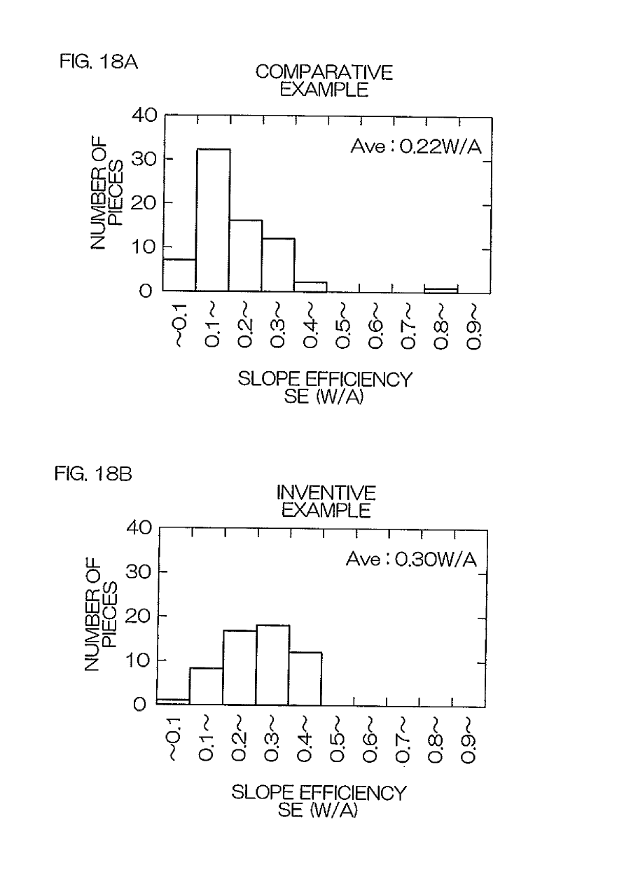

FIG. 18A is a histogram of results of measuring slope efficiencies SE of the plurality of samples according to the comparative example, and FIG. 18B is a histogram of results of measuring the slope efficiencies SE of the plurality of samples according to the inventive example. A comparison of these figures shows that in comparison to the comparative example, the slope efficiency SE is increased by approximately 40% in the inventive example.

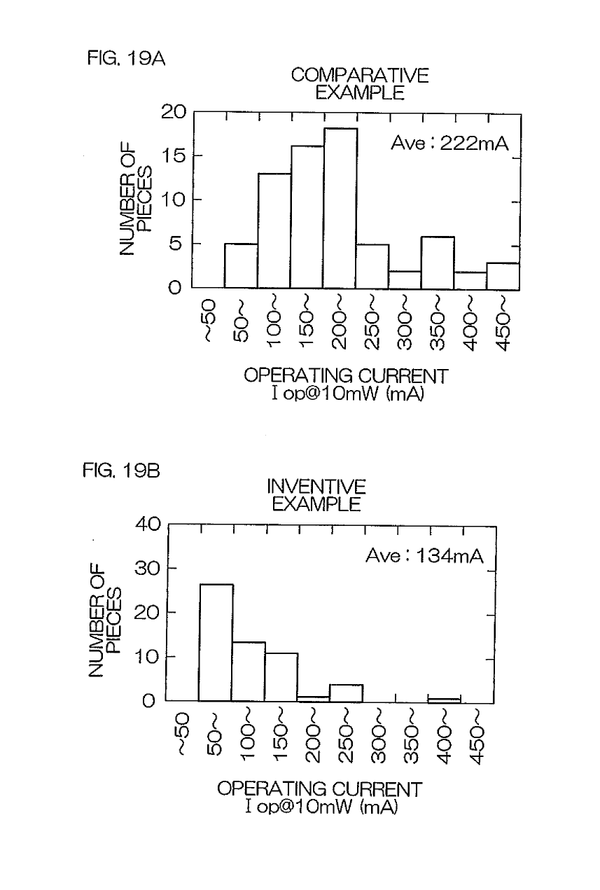

FIG. 19A is a histogram of results of measuring operating currents Iop of the plurality of samples according to the comparative example, and FIG. 19B is a histogram of results of measuring the operating currents Iop of the plurality of samples according to the inventive example. A comparison of these figures shows that in comparison to the comparative example, the operating current Iop is reduced by approximately 40% in the inventive example.

As described above, the semiconductor laminate structure that includes the substrate 1 and the group III nitride semiconductor laminate structure 2 has the end surface processing marks 8 formed in the lower edge regions of the laser resonance surfaces 21 and 22 in the semiconductor laser device 170 of the present preferred embodiment as well. That is, with the semiconductor laser device 170, the end surface processing marks 8 are formed by applying processing from the rear surface side of the semiconductor laminate structure, the original substrate is cleaved by applying the external force upon applying the blade 9 from the top surface side of the semiconductor laminate structure, and the laser resonance surfaces 21 and 22 can be formed by the cleavage planes. The end surface processing marks 8 are formed at the rear surface side at which the ridges 20 are not formed and can thus be formed in a continuous pattern because there is no need to form the marks in a discontinuous pattern with discontinuous portions near the ridges 20. The cleavage by the external force applied from the top surface side can thus be performed with stability and thus satisfactory cleavage planes can be obtained. The semiconductor laser device 170 of excellent characteristics can thereby be provided. Specifically, reduction in the threshold current, increase in the slope efficiency, and reduction in the operating current can be achieved.

Also, with the semiconductor laser device 170, the receiving portions 30 are disposed at positions of the top surface of the group III nitride semiconductor laminate structure 2 that are separated from the ridge 20 in the width direction orthogonal to the longitudinal direction of the ridge 20 and the receiving portions 30 have a height no less than that of the ridge 20, has a length in the width direction that is greater than the width of the ridge 20, and are spaced by an interval from the p-side ohmic electrode 4A. Thus, when the external force is applied upon applying the blade 9 to the top surface side of the wafer 5, all or nearly all of the external force can be made to act on the receiving portions 30. The laser resonance surfaces 21 and 22 that are formed of satisfactory cleavage planes can thereby be formed by dividing (cleaving) the wafer 5, which is the original substrate, while protecting the ridge 20. Moreover, each receiving portion 30 has a length in the width direction that is greater than the width of the ridge 20 and can thus receive the external force reliably. Also, the receiving portions 30 are spaced by intervals from the p-side ohmic electrode 4A and thus the p-side ohmic electrode 4A is not flawed when the external force is received. Current leak and other problems will thus not be caused.

Although preferred embodiments of the present invention have been described, the present invention may be put into practice in yet other modes as well.

For example, in the above-described preferred embodiments, the receiving portions 30 are disposed at both sides of the ridges 20 and the blade 9 is thereby prevented from applying hardly any external force to the ridges 20 when the wafer 5 is divided along the end surface cutting lines 7a. However, if the ridges 20 are not so high in height and the possibility of damaging of the ridges 20 is low, the receiving portions 30 may be omitted.

Also, the compositions of the respective layers making up the group III nitride semiconductor laminate structure 2 are merely those of a single example and may be changed as necessary according to specifications.

Also, although with the preferred embodiment shown in FIG. 1, etc., an example of using the group III nitride semiconductor laminate structure 2 having the {20-21} plane as the major growth surface was described specifically, the semiconductor laser diode structure may instead be made of a group III nitride semiconductor laminate structure having another semipolar plane, such as the {11-22} plane, {01-12} plane, {10-1-1} plane, {10-1-3} plane, {11-24} plane, {10-12} plane, etc., as the major surface (crystal growth surface).

Further, although with the preferred embodiment shown in FIG. 14, etc., an example of using the group III nitride semiconductor laminate structure 2 having the m-plane as the major growth surface was described, the semiconductor laser diode structure may instead be made of a group III nitride semiconductor laminate structure having the a-plane, which is another nonpolar plane, the c-plane, which is a polar plane, or a semipolar plane as the major surface (crystal growth surface). By the present invention, a semiconductor laser device having laser resonance surfaces made of satisfactory cleavage planes can be provided with any of the crystal planes being the crystal growth surface.

Although the preferred embodiments of the present invention have been described in detail, these embodiments are merely specific examples used to clarify the technical contents of the present invention, and the present invention should not be understood as being limited to these specific examples, and the spirit and scope of the present invention are limited solely by the appended claims.

The present application corresponds to Japanese Patent Application No. 2010-272761 and Japanese Patent Application No. 2010-272762 filed in the Japan Patent Office on Dec. 7, 2010 and the entire disclosures of these applications are incorporated herein by reference.

1. A method for manufacturing semiconductor laser device comprising:
a step of preparing an original substrate having a plurality of semiconductor laser device regions arrayed in a matrix, a plurality of ridges formed in stripes so as to pass through each of the plurality of semiconductor laser device regions that are aligned in one direction, and a plurality of receiving portions that are separated from each of the ridges in a width direction orthogonal to a longitudinal direction of the ridge, each of the receiving portions crossing cutting lines set along boundaries of the plurality of semiconductor laser device regions, each of the receiving portions having a height equal to or greater than the ridge;
a scribing step of applying a scribing process to the original substrate along the cutting lines from a rear surface at an opposite side of a top surface at which the ridges are formed, and;
a dividing step of applying a blade to the original substrate along each cutting line from the top surface of the original substrate so as to contact the receiving portions and dividing the original substrate along the cutting line.

2. The method for manufacturing semiconductor laser device according to claim 1, wherein the scribing step includes: a step of applying the scribing process to the original substrate in a continuous manner along the cutting lines.

3. The method for manufacturing semiconductor laser device according to claim 1, wherein the cutting lines include end surface cutting lines set along a direction orthogonal to the ridges, and
the laser resonance surfaces formed of cleavage planes orthogonal to the ridges are formed by performing the dividing step along the end surface cutting lines.

4. The method for manufacturing semiconductor laser device according to claim 1, wherein the cutting lines include side surface cutting lines set along a longitudinal direction of the ridges, and
side surfaces parallel to the ridges are formed by performing the dividing step along the side surface cutting lines.

5. The method for manufacturing semiconductor laser device according to claim 3, further comprising: a step of applying a side surface scribing process to the original substrate from the top surface of the original substrate along side surface cutting lines set parallel to the longitudinal direction of the ridges and along the boundaries of the plurality of semiconductor laser devices; and
a step of dividing the original substrate along the side surface cutting lines by applying a blade to the original substrate from the rear surface of the original substrate and along the side surface cutting lines.

6. The method for manufacturing semiconductor laser device according to claim 5, wherein the side surface scribing step includes: a step of applying the scribing process to the original substrate in a continuous manner along the side surface cutting lines.

7. The method for manufacturing semiconductor laser device according to claim 3, wherein
the cutting lines include side surface cutting lines set along a longitudinal direction of the ridges,
side surfaces parallel to the ridges are formed by performing the dividing step along the side surface cutting lines, and
each of the receiving portions belongs to four semiconductor laser device regions that share an intersection of the end surface cutting line and the side surface cutting line on the top surface of the original substrate.

8. The method for manufacturing semiconductor laser device according to claim 5, wherein each of the receiving portions belongs to four semiconductor laser device regions that share an intersection of the end surface cutting line and the side surface cutting line on the top surface of the original substrate.

9. The method for manufacturing semiconductor laser device according to claim 6, wherein each of the receiving portions belongs to four semiconductor laser device regions that share an intersection of the end surface cutting line and the side surface cutting line on the top surface of the original substrate.

10. The method for manufacturing semiconductor laser device according to claim 1, wherein each of the receiving portions has a length in the width direction that is greater than a width of the ridge.
